(19) United States
(12) Patent Application Publication
(10) Pub. No.: US 2026/0255623 A1
(43) Pub. Date: Aug. 27, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yeh-Hsun FANG, Taipei City (TW); I-Cheng CHANG, Hsinchu City (TW); Yin-Hao WU, Taichung City (TW); Kuo-Chang CHIANG, Hsinchu City (TW); Chi-Min CHEN, Hsinchu City (TW); Po-An CHEN, Kaohsiung City (TW)

(21) Appl. No.: 19/065,457

(22) Filed: Feb. 27, 2025

(51) Int. Cl. H10D 30/01; H10D 30/67

(52) U.S. Cl. CPC H10D 30/0316; H10D 30/6732; H10D 30/6755

(57) ABSTRACT

A transistor structure may be formed in an interconnect layer of a semiconductor device in a process that includes ultraviolet (UV) light curing and ozone (O₃) treatment operations on a gate dielectric layer. The UV light curing and O₃ treatment may remove or reduce impurities formed in the gate dielectric layer. The UV light curing operation may break hydrogen bonds in the gate dielectric layer. The O₃ treatment process repairs the broken bonds, which strengthens metal-oxide bonds for the high-k dielectric material of the gate dielectric layer. The strengthening of the metal-oxide bonds in the gate dielectric layer may prevent oxygen from the gate dielectric layer from reacting with metals in an adjacent gate electrode and oxide-semiconductor channel. As a result, the transistor structure may have a higher breakdown voltage and increased performance in comparison to a transistor structure manufactured without using the UV light curing and O₃ treatment processes.

### BACKGROUND

In some cases, a transistor may be formed in an interconnect layer of a semiconductor device. The interconnect layer may be formed on a device layer of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of a transistor structure described herein.

FIGS. 3A-3F are diagrams of an example implementation of forming the semiconductor device described herein.

FIGS. 4A-4I are diagrams of an example implementation of forming the transistor structure described herein.

FIGS. 5A-5C are diagrams of example implementations of a transistor structure described herein.

FIGS. 6A-6D are diagrams of example implementations of a transistor structure described herein.

FIG. 7 is a graph illustrating a hydrogen profile in a gate dielectric layer of a transistor structure described herein.

FIG. 8 is a flowchart of an example process associated with forming a semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Forming a transistor in an interconnect layer of a semiconductor device often involves the use of different materials and/or structures than those used in transistors formed in a device layer of the semiconductor device. The transistors in the device layer can be formed in a semiconductor substrate of the semiconductor device, whereas transistors formed in the interconnect layer of the semiconductor device are typically formed in a dielectric layer in the semiconductor device. Thus, oxide-semiconductor materials are often used in the channel layers of the transistors in the interconnect layer because oxide-semiconductor materials offer better integration with the dielectric materials used in the interconnect layer, as compared to semiconductor materials used in the channel layers of the transistors in the device layer. In particular, oxide-semiconductor materials may be processed at lower temperatures, may achieve greater nucleation uniformity on dielectric materials, and/or may achieve higher crystallinity (and thus, higher charge carrier mobility and lower off current (I_{off})) on dielectric materials than semiconductor materials such as silicon (Si).

High dielectric constant (high-k) dielectric materials such has hafnium oxide (HfO₂) may be used for a gate dielectric layer between an oxide-semiconductor channel and a gate electrode of a transistor. High-k dielectric materials have higher dielectric constants, enabling the gate dielectric layer to be made thinner while achieving sufficiently low gate leakage and increased gate control in the transistor. However, such high-k dielectric materials are often susceptible to formation of impurities. For example, unwanted impurities, such as hydrogen ions (H⁺), hydroxide ions (OH⁻), and oxygen vacancies (Vo) may be formed in the gate dielectric layer between an oxide-semiconductor channel and a gate electrode of a transistor. The hydrogen and hydroxide ions may be formed from atomic layer deposition (ALD) precursors (e.g., H-based hafnium and water (H₂O) precursors) that may be used during deposition of the gate dielectric layer. The hydrogen and hydroxide ions also may be formed from absorption and/or inter-diffusion of hydrogen from the surrounding environment and/or adjacent hydrogen-rich film layers.

Oxygen vacancies may be intrinsically formed in a gate dielectric layer (e.g., metal oxide film) due to inequalities between amounts of metal and oxygen needed for forming the metal oxide bonds. High charge carrier concentrations caused by the oxygen vacancies may result in lower breakdown voltages, leading to unstable transistor performance and reliability risks. In addition, due to weak and/or loose metal-oxygen bonds near an interface between the gate dielectric layer and the gate electrode, and near an interface between the gate dielectric layer and the oxide-semiconductor channel, oxygen from the gate dielectric layer may react with metals in the adjacent gate electrode and oxide-semiconductor channel.

In some cases, fluorine doping in the gate dielectric layer may be performed to replace the unwanted hydrogen and/or oxygen vacancies. However, excess fluorine may diffuse into the oxide-semiconductor channel and passivate oxygen vacancies in the oxide-semiconductor channel, resulting in unwanted reduction of charge carriers (e.g., electron trapping) in the oxide-semiconductor channel, which can lead to slower switching times and increased hysteresis in the operation of the transistor.

In some implementations described herein, a transistor structure may be formed in an interconnect layer of a semiconductor device. The transistor structure is formed in a process that includes performing ultraviolet (UV) light curing and ozone (O₃) treatment operations on a gate dielectric layer of the transistor structure. The combination of the UV light curing and O₃ treatment may remove or reduce unwanted impurities such as hydrogen ions (H⁺), hydroxide ions (OH⁻), and oxygen vacancies (Vo) that may be formed in the gate dielectric layer between an oxide-semiconductor channel and a gate electrode of the transistor structure. The UV light curing operation may break hydrogen bonds in the gate dielectric layer. The hydrogen bonds may include, for example, hydrogen-oxygen bonds of hydroxides bonded to metals of high-k dielectric material. The O₃ treatment process repairs the broken bonds by replacing oxygen of weak and/or dangling metal-oxygen bonds with oxygen from the ozone, which strengthens metal-oxide bonds for the high-k dielectric material of the gate dielectric layer. The strengthening of the metal-oxide bonds in the gate dielectric layer may prevent oxygen from the gate dielectric layer from reacting with metals in the adjacent gate electrode and oxide-semiconductor channel. Oxygen from the ozone of the O₃ treatment process also passivates oxygen vacancies in the gate dielectric layer. The passivated oxygen vacancies in the gate dielectric layer may reduce charge carrier concentration in the gate dielectric layer. As a result, the transistor structure may have a higher breakdown voltage, increased reliability, and increased performance in comparison to a transistor structure manufactured without using the UV light curing and O₃ treatment processes.

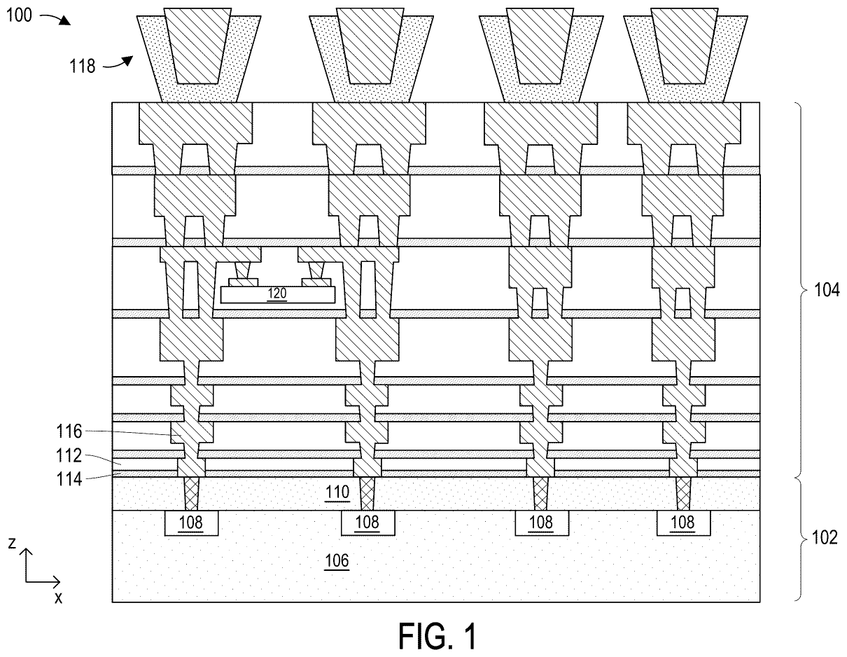

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), and/or another type of semiconductor device.

As shown in FIG. 1, the semiconductor device 100 may include a device layer 102 and an interconnect layer 104 above the device layer 102 in a z-direction in the semiconductor device 100. The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Semiconductor devices 108 may be included in and/or on the substrate 106 in the device layer 102 of the semiconductor device 100. The semiconductor devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the semiconductor devices 108 to be selectively etched or protected from etching, and/or to electrically isolate the semiconductor devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the semiconductor devices 108 in the z-direction in the semiconductor device 100. The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 112 and ESLs 114 that are arranged in an alternating manner in the z-direction. The ILD layers 112 and the ESLs 114 may extend in the x-direction and/or in the y-direction in the semiconductor device 100.

The ILD layers 112 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 112 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 114 may each include a silicon nitride (SiₓN_{y}), silicon carbide (SiC), silicon oxynitride (SiON), and/or another suitable dielectric material. In some implementations, an ILD layer 112 and an ESL 114 include different dielectric materials to provide etch selectivity to enable various structures to be formed in the interconnect layer 104.

The interconnect layer 104 includes a plurality of conductive structures 116. One or more of the conductive structures 116 are electrically coupled and/or physically coupled with one or more of the semiconductor devices 108 in the device layer 102. The conductive structures 116 provide electrical routing that enables signals and/or power to be provided to and/or from the semiconductor devices 108. The conductive structures 116 may include a combination of vias, trenches, contacts, plugs, interconnects, metallization layers, conductive traces, and/or other types of conductive structures. The conductive structures 116 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the conductive structures 116 and the ILD layers 112, and/or between the conductive structures 116 and the ESLs 114. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 116 of the interconnect layer 104 may be arranged in in a vertical manner (e.g., in the z-direction). In other words, a plurality of stacked conductive structures 116 extend between the device layer 102 and connection structures 118 above the interconnect layer 104 to facilitate electrical signals and/or power to be routed between the device layer 102 and the connection structures 118. The plurality of stacked conductive structures 116 may be referred to as M-layers. For example, a metal-0 (M0) layer may located at the bottom of the interconnect layer 104 and may be directly coupled with the device layer 102 (e.g., with the contacts or vias of the semiconductor devices 108 in the device layer 102), a metal-1 layer (M1) layer may be located above the M0 layer in the interconnect layer 104, a metal-2 layer (M2) layer may be located above the M1 layer, and so on. Additionally, via layers may be included between vertically arranged M-layers. For example, a via-1 (V1) layer may be included between the M1 layer and the M2 layer to interconnect the M1 layer and the M2 layer, a via-2 (V2) layer may be included between the M2 layer and the M3 layer to interconnect the M2 layer and the M3 layer, and so on.

The connection structures 118 include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. The connection structures 118 enable the semiconductor device 100 to be attached to a semiconductor device package substrate (e.g., an interposer, a redistribution layer (RDL) structure, a printed circuit board (PCB)) and/or to another semiconductor device.

One or more semiconductor devices are also included in the interconnect layer 104 of the semiconductor device 100. For example, a transistor structure 120 (e.g., semiconductor structure) is included in an ILD layer 112 of the interconnect layer 104. The transistor structure 120 may be referred to as an interconnect layer transistor structure or interconnect region transistor structure in that the transistor structure 120 is included in the interconnect layer 104 of the semiconductor device 100 as opposed to the device layer 102 of the semiconductor device 100. The transistor structure 120 is electrically coupled and/or physically coupled with one or more conductive structures 116 in the interconnect layer 104.

In some implementations, the transistor structure 120 may be electrically coupled to a capacitor in the interconnect layer 104. The combination of the transistor structure 120 and the capacitor may correspond to a memory cell (e.g., a dynamic random access memory (DRAM) cell) in the interconnect layer 104. In some implementations, the transistor structure 120 includes a memory layer (e.g., a ferroelectric memory layer, a resistive memory layer, a floating memory layer) such that the transistor structure 120 corresponds to a transistor-based memory cell (e.g., a ferroelectric field effect transistor (FeFET) memory cell, floating gate transistor memory cell).

As indicated above, FIG. 1 is provided as an example. Other examples may differ from what is described with regard to FIG. 1.

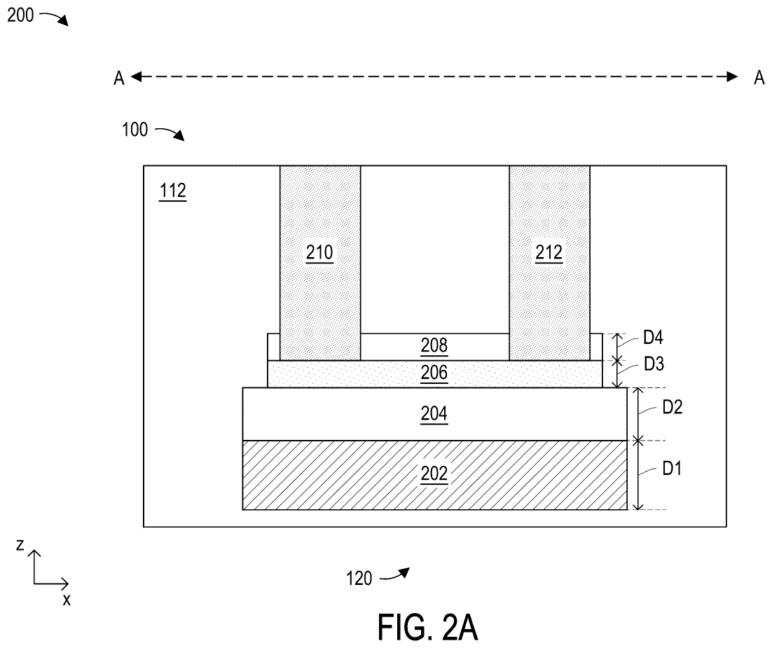

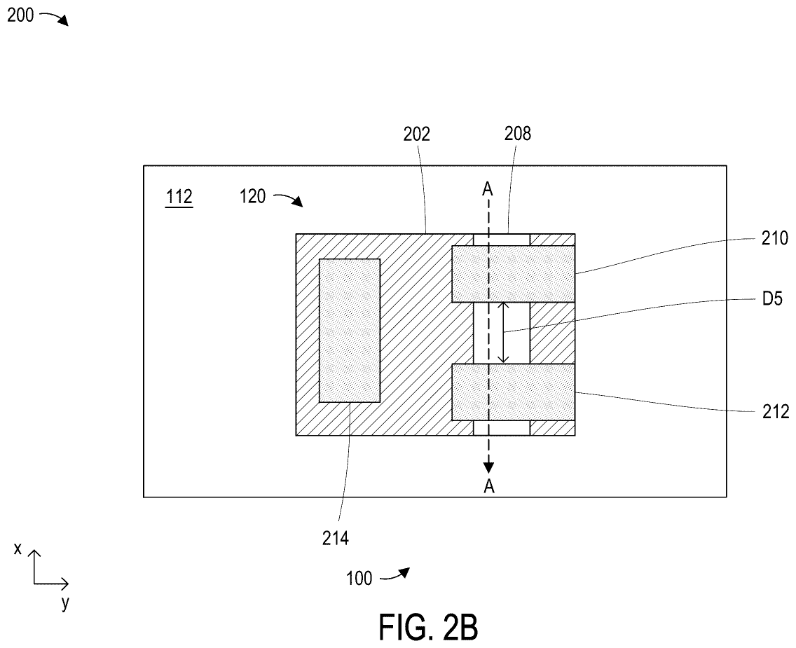

FIGS. 2A and 2B are diagrams of an example implementation 200 of a transistor structure 120 described herein. As described in connection with FIG. 1, the transistor structure 120 may be referred to as an interconnect layer transistor structure or an interconnect region transistor structure that is included in an ILD layer 112 in the interconnect layer 104 of the semiconductor device 100. The transistor structure 120 may also be referred to as a thin-film transistor (TFT) in that one or more layers (e.g., a gate dielectric layer, a channel layer) of the transistor structure 120 are formed as thin films using thin-film deposition techniques. The transistor structure 120 includes an oxide-semiconductor channel layer, which enables the manufacturing process for the transistor structure 120 to be integrated into the manufacturing process for the interconnect layer 104.

FIG. 2A illustrates a cross-section view of the transistor structure 120. The transistor structure 120 may include a gate electrode 202. The gate electrode 202 may be referred to as a bottom gate electrode or a buried gate electrode in that the gate electrode 202 is located at the bottom of the transistor structure 120. The gate electrode 202 may be electrically coupled with a gate contact, as shown in FIG. 2B. The gate electrode 202 may include one or more electrically conductive metal materials. Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof, among other examples. In some implementations, a z-direction thickness of the gate electrode 202 (indicated in FIG. 2A as a dimension D1) is included in a range of approximately 50 angstroms to approximately 500 angstroms. However, other values and/or ranges for the z-direction thickness of the gate electrode 202 are within the scope of the present disclosure.

The transistor structure 120 includes a gate dielectric layer 204. The gate dielectric layer 204 may be included over and/or on the gate electrode 202. The gate dielectric layer 204 may be a high-k gate dielectric layer in that the gate dielectric layer 204 may include one or more high-k dielectric materials that have a dielectric constant greater than the dielectric constant of silicon dioxide (SiO₂—approximately 3.9 dielectric constant). Examples of such high-k dielectric materials include metal-oxide materials having a dielectric constant that is greater than or approximately equal to 9, such as hafnium oxide (HfOₓ such as HfO₂), aluminum oxide (AlₓO_{y} such as Al₂O₃), and/or zirconium oxide (ZrOₓ such as ZrO₂), among other examples. In some implementations, the gate dielectric layer 204 may include an oxide material that includes two or more of hafnium (Hf), titanium (Ti), lanthanum (La), silicon (Si), thallium (Tl), and/or zirconium (Zr). Examples of such dielectric materials include hafnium titanium oxide (HfₓTi_{y}O_{z}), hafnium lanthanum oxide (HfₓLa_{y}O_{z}), hafnium silicon oxide (HfₓSi_{y}O_{z}), hafnium thallium oxide (HfₓTl_{y}O_{z}), and/or hafnium zirconium oxide (HfₓZr_{y}O_{z}), among other examples. Additionally and/or alternatively, the gate dielectric layer 204 may include a silicon oxide (SiOₓ such as SiO₂) and/or a low-k dielectric layer.

In some implementations, as shown in FIG. 2A, the gate dielectric layer 204 is in direct contact with (e.g., directly disposed on) the gate electrode 202. For example, a bottom surface of the gate dielectric layer 204 is in direct contact with a top surface of the gate electrode 202, with no intervening layers between the gate electrode 202 and the gate dielectric layer 204. As noted herein, the gate dielectric layer 204 is treated with UV light and ozone. Ozone from the O₃ treatment process provides oxygen to replace oxygen of weak and/or dangling metal-oxygen bonds in the gate dielectric layer 204, which strengthens metal-oxide bonds for the high-k dielectric material of the gate dielectric layer 204. The strengthening of the metal-oxide bonds in the gate dielectric layer 204 may prevent oxygen from the gate dielectric layer 204 from reacting with metals in the adjacent gate electrode 202, which may prevent or limit the formation of interfacial layers between the gate electrode 202 and the gate dielectric layer 204. The interfacial layers may include a metal material of the gate electrode 202 and oxygen from the gate dielectric layer 204. Strengthening of the metal-oxide bonds in the gate dielectric layer 204 may prevent or reduce the likelihood of formation of native oxides on the gate electrode 202 that might otherwise form due to oxidation of the surface of the gate electrode 202 with oxygen from the gate dielectric layer 204. Strengthening of the metal-oxide bonds in the gate dielectric layer 204 may reduce the likelihood and/or magnitude of charge trapping that might otherwise occur at the interface between the gate dielectric layer 204 and the gate electrode 202.

The gate dielectric layer 204 may include a thin-film layer having a z-direction thickness (indicated in FIG. 2A as a dimension D2) that is included in a range of approximately 30 angstroms to approximately 150 angstroms. However, other values and/or ranges for the z-direction thickness of the gate dielectric layer 204 are within the scope of the present disclosure.

In some implementations, the gate dielectric layer 204 may function as a memory layer of the transistor structure 120. For example, the gate dielectric layer 204 may include a ferroelectric material for which an electric polarization can be switched between two or more discrete polarization states by applying an external electric field to the gate dielectric layer 204. The polarization states correspond to different values for data stored in the transistor structure 120. Examples of such ferroelectric materials include aluminum scandium nitride (e.g., AlScN), PBT (e.g., PbZrO₃), PZT (e.g., Pb[ZrₓTi₁₋ₓ]O₃, (0≤x≤1)), PLZT (e.g., Pb₁₋ₓLaₓZr_{1-y}Ti_{y}O₃), barium titanate (e.g., BaTiO₃), lead titanate (e.g., PbTiO₃), lead metaniobate (e.g., PbNb₂O₆), lithium niobate (e.g., LiNbO₃), lithium tantalate (e.g., LiTaO₃), PMN (e.g., PbMg₁₋₃Nb_{2/3}O₃), PST (e.g., PbSc_{1/2}Ta_{1/2}O₃), SBT (e.g., SrBi₂Ta₂O₉), BNT (e.g., Bi_{1/2}Na_{1/2}TiO₃), and/or combinations thereof, among other examples. In some implementations, the ferroelectric material may include dopants such as scandium (Sc), lanthanum (La), calcium (Ca), barium (Ba), yttrium (Y), strontium (Sr), zirconium (Zr), silicon (Si), aluminum (Al), scandium (Sc), indium (In), and/or gadolinium (Gd), among other examples. For example, the ferroelectric material may include hafnium oxide doped with zirconium (e.g., Zr: HfO₂), hafnium oxide doped with silicon (e.g., Si: HfO₂), hafnium oxide doped with lanthanum (e.g., La: HfO₂), hafnium oxide doped with aluminum (e.g., Al:HfO₂), hafnium oxide doped with tantalum (Ta:HfO₂), hafnium oxide doped with scandium (e.g., Sc:HfO₂), hafnium oxide doped with yttrium (e.g., Y:HfO₂), hafnium oxide doped with strontium (e.g., Sr:HfO₂), hafnium oxide doped with indium (e.g., In:HfO₂), and/or hafnium oxide doped with gadolinium (e.g., Gd:HfO₂), among other examples.

The transistor structure 120 includes an oxide-semiconductor channel layer 206 above the gate dielectric layer 204. In some implementations, a capping layer 208 may be included on the oxide-semiconductor channel layer 206 or may be omitted. The oxide-semiconductor channel layer 206 includes one or more oxide-semiconductor materials. Examples of such oxide-semiconductor materials such as tin oxide (e.g., SnO or SnO₂), indium gallium zinc oxide (InGaZnO or IGZO), indium gallium oxide (InGaO or IGO), indium zinc oxide (InZnO or IZO), indium tungsten oxide (InWO or IWO), among other examples. In some implementations, the oxide-semiconductor channel layer 206 includes an oxide-semiconductor material that includes indium (In), gallium (Ga), zinc (Zn), and one or more additional metals such as titanium (Ti), aluminum (Al), silver (Ag), vanadium (V), scandium (Sc), tungsten (W), tin (Sn), cerium (Ce), among other examples. For example, the oxide-semiconductor channel layer 206 may include InₓGa_{y}Zn_{z}MO, where M corresponds to one or more of the above-described metals, where 0≤x≤1, where 0≤y≤1, and where 0≤z≤1.

In some implementations, as shown in FIG. 2A, the oxide-semiconductor channel layer 206 is in direct contact with (e.g., directly disposed on) the gate dielectric layer 204. For example, a bottom surface of the oxide-semiconductor channel layer 206 is in direct contact with a top surface of the gate dielectric layer 204, with no intervening layers between the oxide-semiconductor channel layer 206 and the gate dielectric layer 204. As noted herein, the gate dielectric layer 204 is treated with UV light and ozone. Ozone from the O₃ treatment process provides oxygen to replace oxygen of weak and/or dangling metal-oxygen bonds in the gate dielectric layer 204, which strengthens metal-oxide bonds for the high-k dielectric material of the gate dielectric layer 204. The strengthening of the metal-oxide bonds in the gate dielectric layer 204 may prevent oxygen from the gate dielectric layer 204 from reacting with metals in the adjacent oxide-semiconductor channel layer 206, which may prevent or limit the formation of interfacial layers between the oxide-semiconductor channel layer 206 and the gate dielectric layer 204. The interfacial layers may include a metal material of the oxide-semiconductor channel layer 206 and oxygen from the gate dielectric layer 204. Strengthening of the metal-oxide bonds in the gate dielectric layer 204 may prevent or reduce the likelihood of formation of native oxides on the oxide-semiconductor channel layer 206 that might otherwise form due to oxidation of the surface of the oxide-semiconductor channel layer 206 with oxygen from the gate dielectric layer 204. Strengthening of the metal-oxide bonds in the gate dielectric layer 204 may reduce the likelihood and/or magnitude of charge trapping that might otherwise occur at the interface between the gate dielectric layer 204 and the oxide-semiconductor channel layer 206.

The electrical conductivity of the oxide-semiconductor channel layer 206 is capable of being selectively controlled by the gate electrode 202 to selectively enable an electrical current to flow between source/drain electrodes 210 and 212 of the transistor structure 120. When a voltage is applied to the gate electrode 202, the oxide-semiconductor channel layer 206 may become electrically conductive, thereby enabling the electrical current to flow between source/drain electrodes 210 and 212. Conversely, when the voltage is removed from the gate electrode 202, the oxide-semiconductor channel layer 206 may become electrically non-conductive, thereby preventing the electrical current from flowing between source/drain electrodes 210 and 212.

The oxide-semiconductor channel layer 206 may be a thin-film layer having a z-direction thickness (indicated in FIG. 2A as a dimension D3) that is included in a range of approximately 30 angstroms to approximately 200 angstroms. However, other values and/or ranges for the z-direction thickness of the oxide-semiconductor channel layer 206 are within the scope of the present disclosure. The capping layer 208 may be thin-film layer having a z-direction thickness (indicated in FIG. 2A as a dimension D4) that is included in a range of approximately 10 angstroms to approximately 200 angstroms. However, other values and/or ranges for the z-direction thickness of the capping layer 208 are within the scope of the present disclosure. The capping layer 208 may include one or more dielectric materials, such as silicon oxide (SiOₓ such as SiO₂), hafnium oxide (HfOₓ such as HfO₂), aluminum oxide (AlₓO_{y} such as Al₂O₃), titanium oxide (TiOₓ such as TiO₂), and/or another suitable dielectric material.

The source/drain electrodes 210 and 212 may be included above and/or on the oxide-semiconductor channel layer 206. The source/drain electrodes 210 and 212 may be in direct physical contact with the oxide-semiconductor channel layer 206, or one or more layers (e.g., liners, barrier layers, adhesion layers) may be included between the oxide-semiconductor channel layer 206 and the source/drain electrodes 210 and 212. “Source/drain electrode” may refer to a source electrode or a drain electrode, individually or collectively, dependent upon the context. The source/drain electrodes 210 and 212 may each include one or more electrically conductive materials, such one or more metals and/or one or more metal-containing materials, among other examples. Examples of such materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof, among other examples. In some implementations, the z-direction thickness of each of the source/drain electrodes 210 and 212 is included in a range of approximately 50 angstroms to approximately 500 angstroms. In some implementations, the z-direction thickness of each of the source/drain electrodes 210 and 212 is greater than approximately 5 nanometers. However, other values and/or ranges for the z-direction thickness of each of the source/drain electrodes 210 and 212 are within the scope of the present disclosure.

The source/drain electrodes 210 and 212 may each be electrically coupled with a conductive structure 116 in the interconnect layer 104 of the semiconductor device 100. This enables electrical inputs (e.g., voltages, electrical currents) to be applied to the source/drain electrode 210 and/or the source/drain electrode 212, and/or enables the source/drain electrode 210 and/or the source/drain electrode 212 to be electrically grounded. Additionally and/or alternatively, the source/drain electrode 210 and/or 212 may be electrically coupled with a capacitor structure through one or more conductive structures 116 in the interconnect layer 104.

FIG. 2B illustrates a top view of the transistor structure 120 and a location of the cross-section along line A-A in FIG. 2A. As shown in FIG. 2B, the source/drain electrodes 210 and 212 may extend laterally outward past the sides of the oxide-semiconductor channel layer 206 in the y-direction in the semiconductor device 100. Similarly, the gate electrode 202 may extend laterally outward past the sides of the oxide-semiconductor channel layer 206, as well as laterally outward past the source/drain electrodes 210 and 212, in the y-direction in the semiconductor device 100. This enables a gate contact 214 to be formed on the gate electrode 202.

As further shown in FIG. 2B, the source/drain electrodes 210 and 212 are spaced apart in the x-direction, enabling a conductive channel to be selectively formed between the source/drain electrodes 210 and 212 through the oxide-semiconductor channel layer 206. A distance between the source/drain electrodes 210 and 212 (indicated in FIG. 2B as dimension D5) corresponds to a gate length (L_{g}) of the transistor structure 120. In some implementations, the gate length may be included in a range of approximately 1 nanometer to approximately 100 nanometers. However, other values and ranges for the gate length are within the scope of the present disclosure.

As indicated above, FIGS. 2A and 2B are provided as an example. Other examples may differ from what is described with regard to FIGS. 2A and 2B.

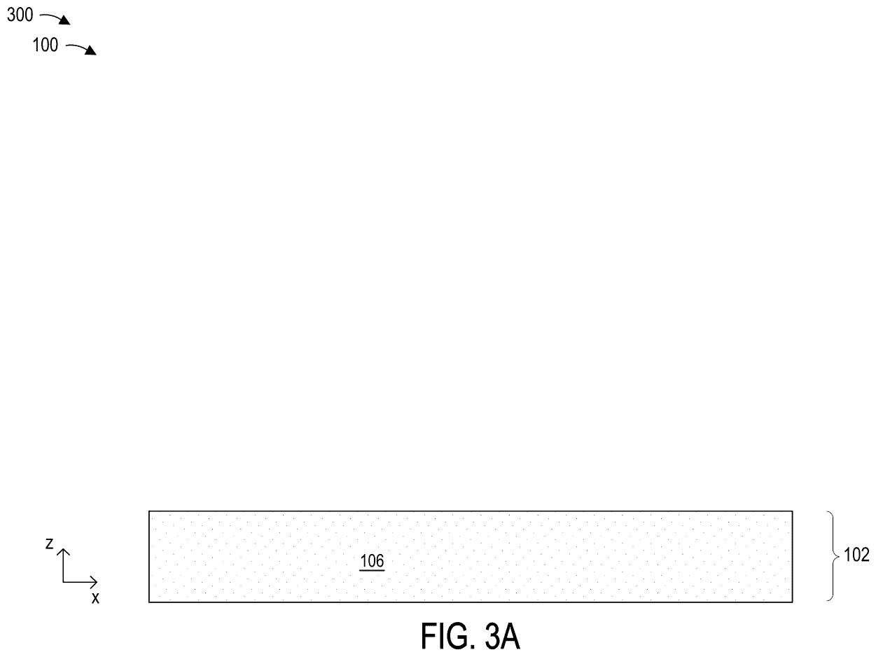

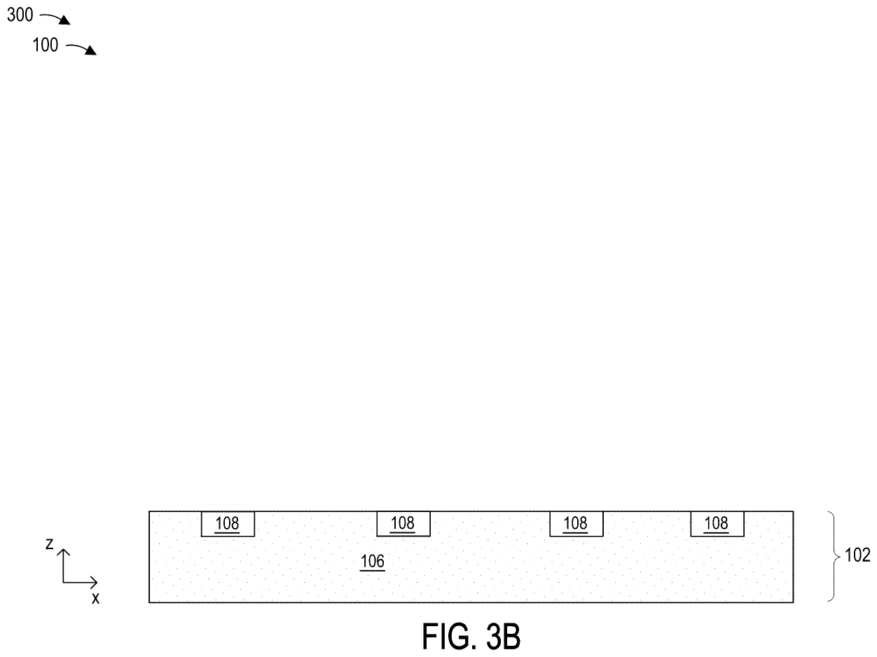

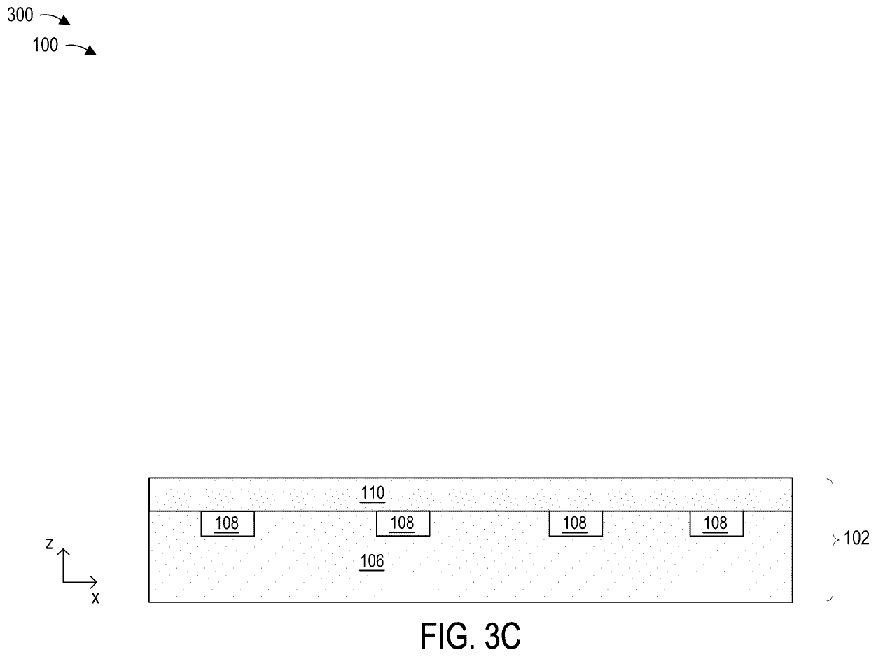

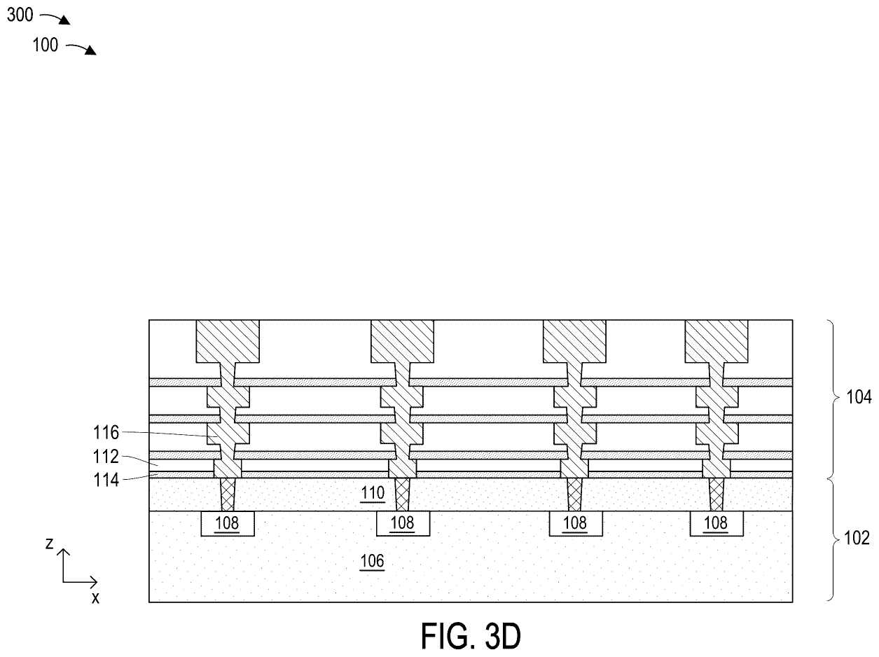

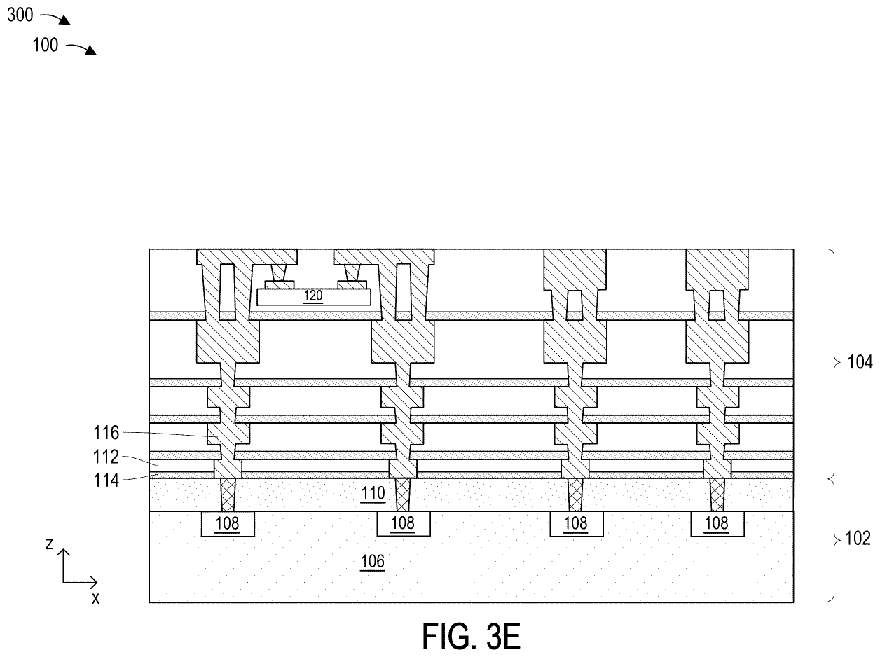

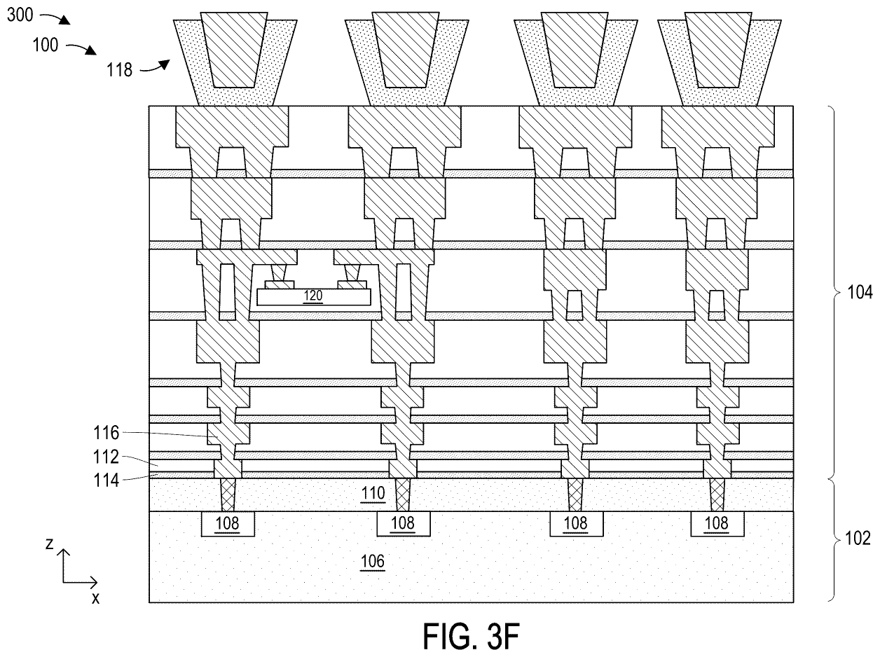

FIGS. 3A-3F are diagrams of an example implementation 300 of forming the semiconductor device 100 described herein. In some implementations, one or more of the semiconductor processing operations described in connection with FIGS. 3A-3F may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 106 is provided. The substrate 106 may be provided in the form of a semiconductor wafer such as a silicon (Si) wafer may be provided as an SOI wafer, and/or another type of semiconductor work piece.

As shown in FIG. 3B, the semiconductor devices 108 (e.g., the device region semiconductor devices) may be formed in and/or on the substrate 106 in the device layer 102 of the semiconductor device 100. One or more semiconductor processing tools may be used to form one or more portions of the semiconductor devices 108. For example, a deposition tool may be used to perform various deposition operations to deposit layers and/or structures of the semiconductor devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the semiconductor devices 108. As another example, a planarization tool may be used to planarize portions of the semiconductor devices 108. As another example, a plating tool may be used to deposit metal structures and/or layers of the semiconductor devices 108.

As shown in FIG. 3C, a deposition tool is used to deposit the dielectric layer 110 over and/or on the substrate 106 and over and/or on the semiconductor devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to planarize the dielectric layer 110 after the dielectric layer 110 is deposited.

As shown in FIG. 3D, a first portion of the interconnect layer 104 of the semiconductor device 100 is formed above the dielectric layer 110. One or more deposition tools are used to deposit alternating layers of ILD layers 112 and ESLs 114 in the first portion of the interconnect layer 104 of the semiconductor device 100. In this way, the ILD layers 112 and ESLs 114 may be arranged in the z-direction in the semiconductor device 100. One or more deposition tools may be used to deposit each of the ILD layers 112 and each of the ESLs 114 using a PVD technique, an ALD technique, a CVD technique, an oxidation technique, and/or another suitable deposition technique. In some implementations, a planarization tool may be used to planarize the ILD layers 112 and/or the ESLs 114 after the ILD layers 112 and/or the ESLs 114 are deposited.

As further shown in FIG. 3D, a deposition tool, an exposure tool, a developer tool, an etch tool, a planarization tool, and/or a plating tool are used to perform various operations to form the conductive structures 116 in the first portion of the interconnect layer 104 of the semiconductor device 100. The conductive structures 116 may be included in the ILD layers 112 and/or the ESLs 114, and may be electrically coupled with the semiconductor devices 108 in the device layer 102. In some implementations, the ILD layers 112, the ESLs 114, and the conductive structures 116 may built up in the z-direction in metallization layers. For example, a first ESL 114 and a first ILD layer 112 may be formed, recesses may be formed in first ESL 114 and/or in the first ILD layer 112, and first conductive structures 116 (e.g., an M0 metallization layer) may be formed in the recesses. A second ESL 114 and a second ILD layer 112 may be formed above the first ESL 114 and the first ILD layer 112, recesses may be formed in second ESL 114 and/or in the second ILD layer 112, and second conductive structures 116 (e.g., an M1 metallization layer) may be formed in the recesses. The remaining metallization layers of the first portion of the interconnect layer 104 may be formed in a similar manner. Additionally, via layers may be formed to interconnect the metallization layers in the interconnect layer 104. The via layers may include conductive structures 116 corresponding to vias or interconnects that interconnect two or more metallization layers in the interconnect layer 104.

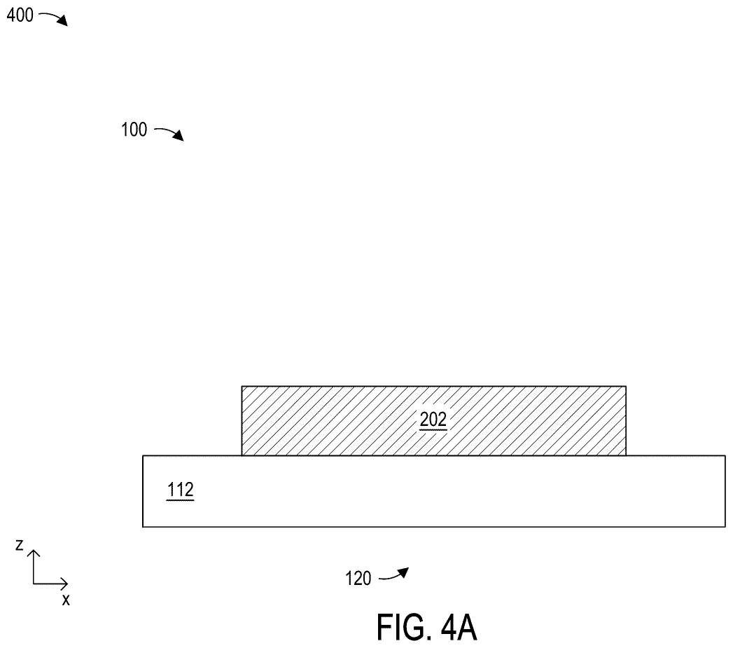

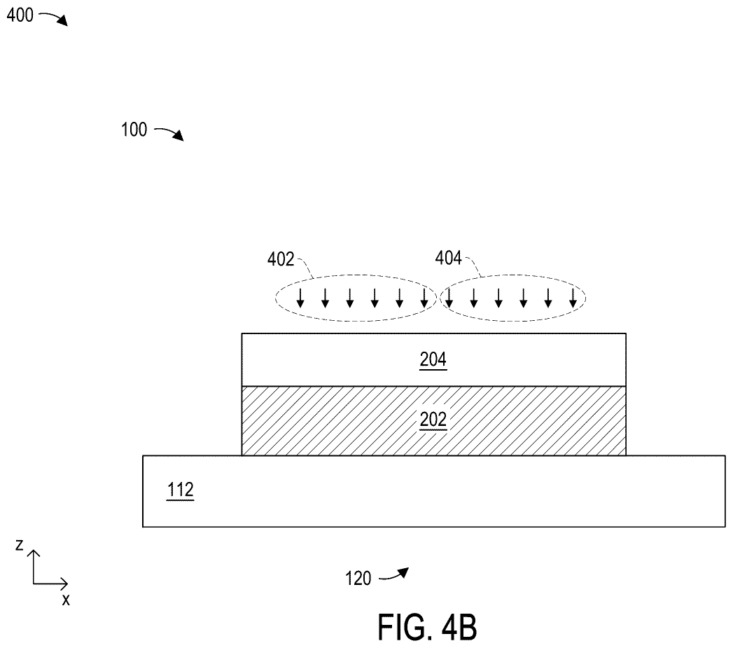

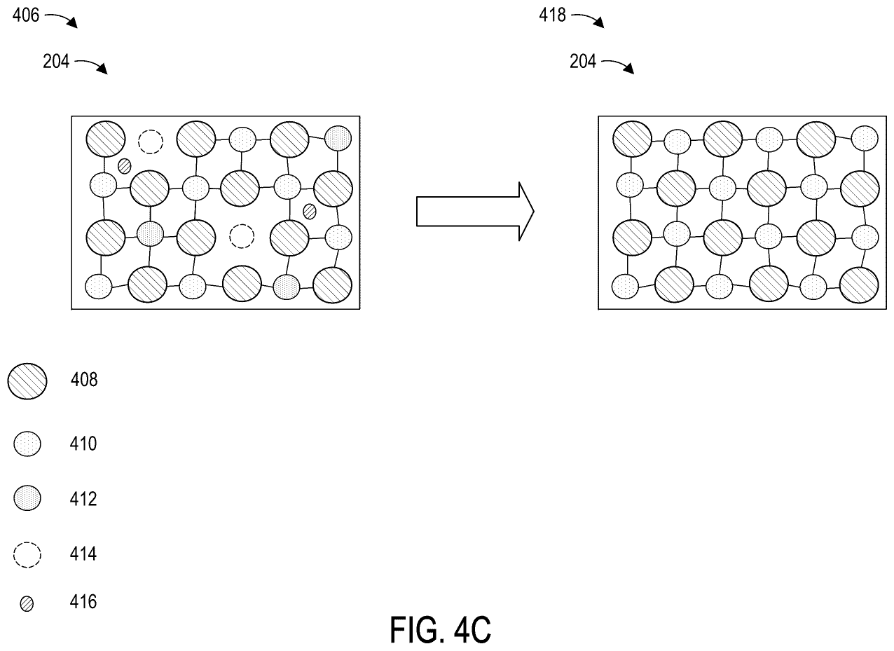

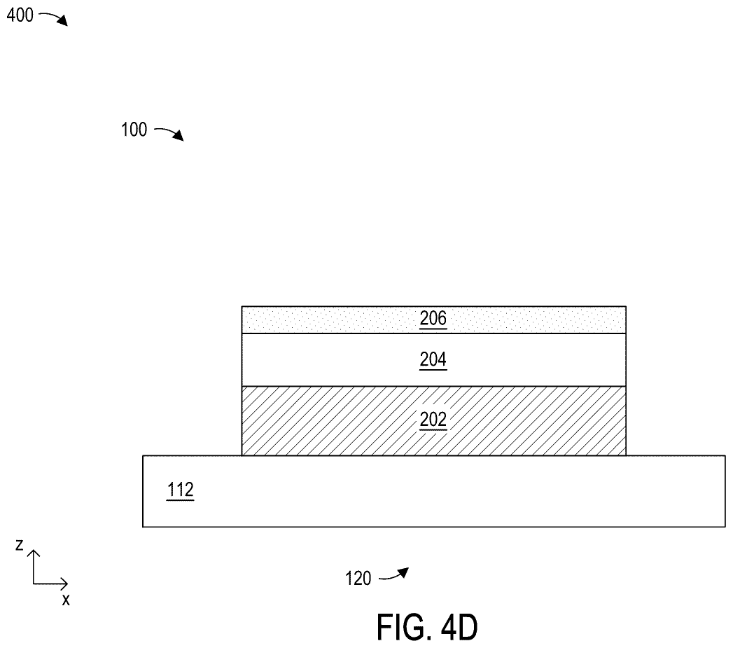

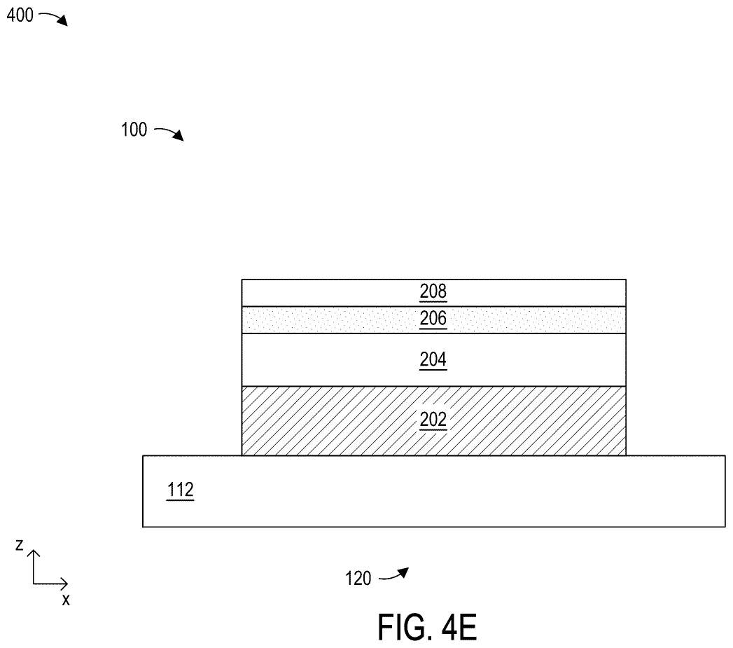

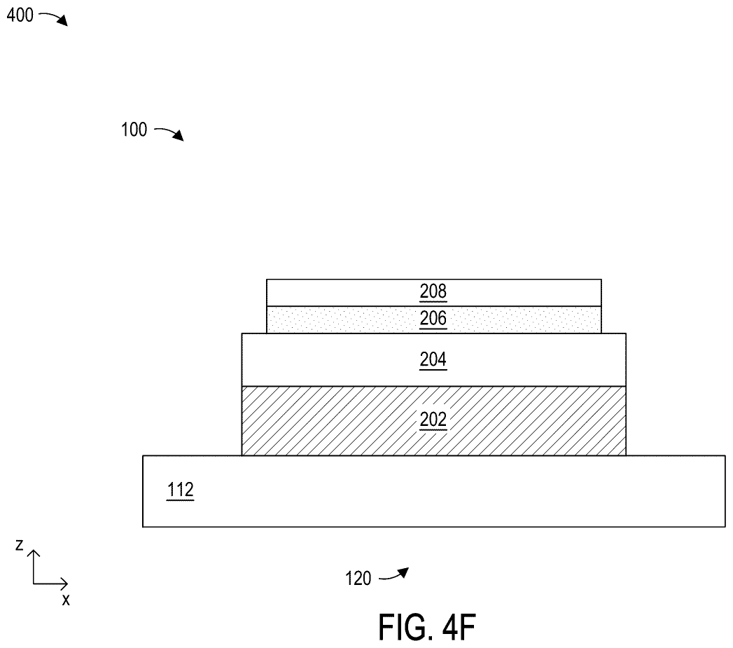

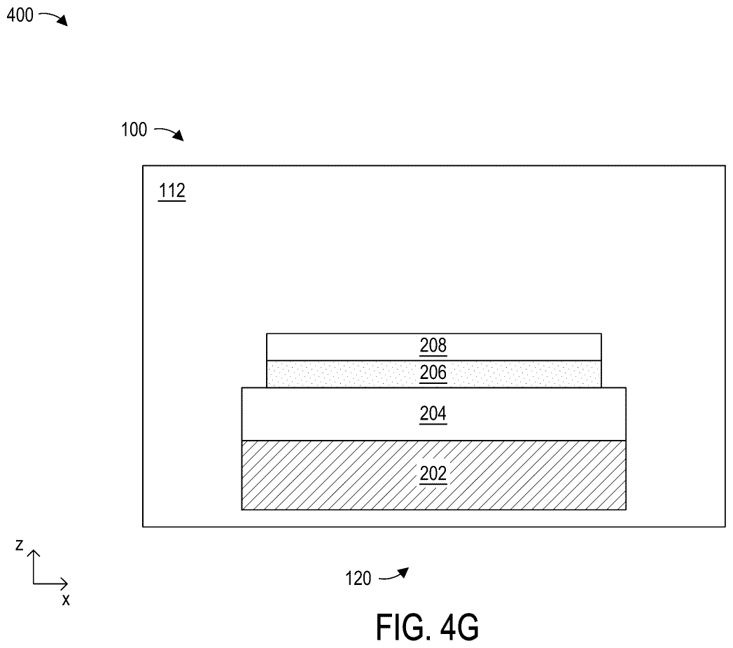

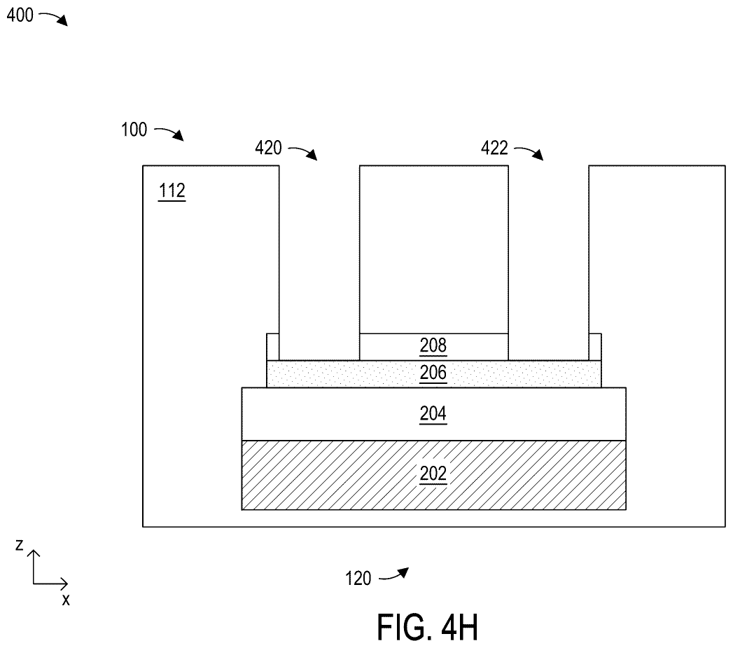

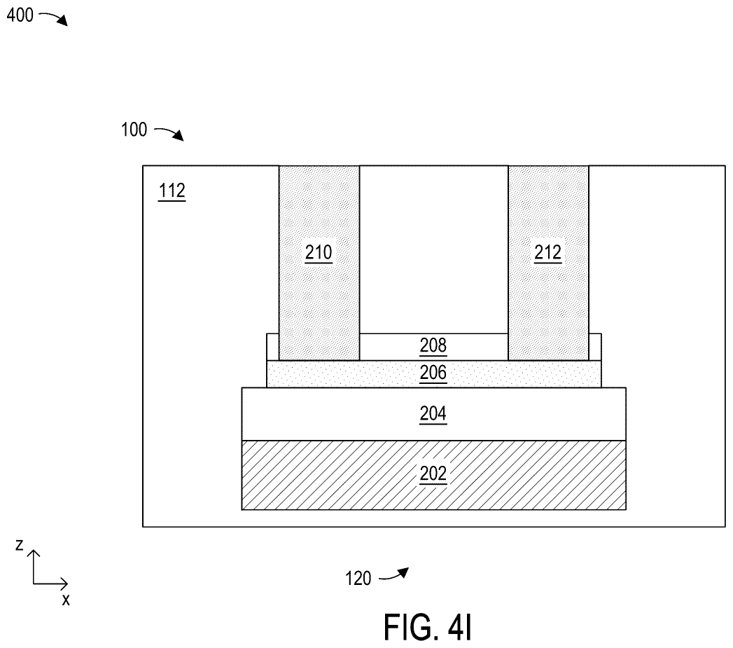

As shown in FIG. 3E, a second portion of the interconnect layer 104 of the semiconductor device 100 is formed over and/or on the first portion of the interconnect layer 104. Techniques similar to those described in connection with FIG. 3D may be performed to form the second portion of the interconnect layer 104. Additionally, a transistor structure 120 (e.g., an interconnect layer transistor structure or an interconnect region transistor structure) is formed in an ILD layer 112 in the second portion of the interconnect layer 104. Conductive structures 116 may be formed on the transistor structure 120 to electrically connect the transistor structure 120 in the interconnect layer 104. An example implementation of forming the transistor structure 120 is illustrated and described in connection with FIGS. 4A-4I.

As shown in FIG. 3F, a third portion of the interconnect layer 104 may be formed above the second portion of the interconnect layer 104 that includes the transistor structure 120. The third portion of the interconnect layer 104 may be formed using a similar combination of techniques as described in connection with FIGS. 3D and 3E.

As further shown in FIG. 3F, the connection structures 118 are formed on the interconnect layer 104 such that the connection structures 118 are electrically coupled and/or physically coupled with one or more conductive structures 116 in the interconnect layer 104. A deposition tool may be used to deposit the connection structures 118 using a CVD technique, a PVD technique, an ALD technique, an electroplating technique, and/or a deposition technique other than as described above in connection with FIG. 1. In some implementations, a semiconductor packaging tool attaches the connection structures 118 to the semiconductor device 100.

As indicated above, FIGS. 3A-3F are provided as an example. Other examples may differ from what is described with regard to FIGS. 3A-3F.

FIGS. 4A-4I are diagrams of an example implementation 400 of forming the transistor structure 120 described herein. In some implementations, one or more of the semiconductor processing operations described in connection with FIGS. 4A-4I may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 4A, the operations described in the example implementation 400 may be performed in connection with an ILD layer 112 of the interconnect layer 104 of the semiconductor device 100. The operations described in the example implementation 400 may be performed in connection with forming the semiconductor device 100, as described in connection with FIGS. 3A-3F. For example, the operations described in the example implementation 400 may be performed in connection with forming the interconnect layer 104, as described in connection with FIG. 3E.

As shown in FIG. 4A, the gate electrode 202 may be formed on the ILD layer 112. A deposition tool may deposit the gate electrode 202 using a CVD technique, a PVD technique, an ALD technique, an electroplating technique, and/or a deposition technique other than as described above in connection with FIG. 1. In some implementations, a planarization tool may be used to perform a chemical mechanical planarization (CMP) operation to planarize the gate electrode 202 after the gate electrode 202 is deposited.

As shown in FIG. 4B, the gate dielectric layer 204 may be formed over and/or on the gate electrode 202. A deposition tool may be used to deposit the gate dielectric layer 204 using an ALD technique, a CVD technique, a PVD technique, and/or another suitable deposition technique. In some implementations, a planarization tool is used to perform a CMP operation to planarize the gate dielectric layer 204 after the gate dielectric layer 204 is deposited.

As further shown by the arrows 402 and 404 in FIG. 4B, which respectively represent a UV light curing operation and an O₃ treatment operation, the gate dielectric layer 204 UV light curing and O₃ treatment operations are performed on the gate dielectric layer 204. In some implementations, the UV light treatment operation and the O₃ treatment operation are performed simultaneously. Alternatively, the O₃ treatment operation may be performed after the UV light treatment operation.

Unwanted impurities, such as hydrogen ions (H⁺), hydroxide ions (OH⁻), and oxygen vacancies (Vo) may be formed in the gate dielectric layer 204. The combination of the UV light curing and O₃ treatment may remove or reduce unwanted impurities such as hydrogen ions (H⁺), hydroxide ions (OH⁻), and oxygen vacancies (Vo) that may be formed in the gate dielectric layer 204. The UV light curing operation may break hydrogen bonds in the gate dielectric layer 204. The hydrogen bonds may include, for example, hydrogen-oxygen bonds of hydroxides bonded to metals of high-k dielectric material. Performing the UV light treatment operation may include exposing the gate dielectric layer 204 to UV light having a wavelength included in a range of approximately 100 nanometers to approximately 440 nanometers. If the wavelength is smaller than 100 nm, thermal damage to the transistor structure 120 and/or to one or more components of the semiconductor device 100 may occur. If the wavelength is greater than 440 nanometers, energy may not be sufficient to break the hydrogen bonds. However, other values and/or ranges for the wavelength of the UV light are within the scope of the present disclosure.

A time for performing the UV light treatment operation may be included in a range of approximately 30 seconds to approximately 300 seconds. If the time is greater than 300 seconds, excessive damage to metal-oxygen bonds (e.g., to strong metal-oxygen bonds) in the gate dielectric layer 204 may occur. If the time is less than 30 seconds, energy may not be sufficient to break the hydrogen bonds. However, other values and/or ranges for the wavelength of the UV light are within the scope of the present disclosure.

The O₃ treatment process repairs broken bonds in the gate dielectric layer 204 by replacing oxygen of weak and/or dangling metal-oxygen bonds in the gate dielectric layer 204 with oxygen from the ozone, which strengthens metal-oxide bonds for the high-k dielectric material of the gate dielectric layer 204.

Oxygen from the ozone of the O₃ treatment process also passivates oxygen vacancies in the gate dielectric layer 204. In more detail, at least a portion of the ozone in the mixture is formed into one or more oxygen ions (e.g., O²⁻ ions), where the one or more oxygen ions passivate one or more oxygen vacancies in the gate dielectric layer 204. The decomposition of a molecule of ozone may include ozone breaking down into molecular oxygen (e.g., O₂) and a free oxygen atom (O). The free oxygen atom may further react with other molecules to form an oxygen ion (e.g., O²⁻ ion).

For example, the following reaction (1) illustrates breaking of a metal-oxygen bond in the gate dielectric layer 204:

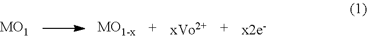

where M represents a metal and e⁻ represents an electron.

The following reaction (2) illustrates repairing of a broken metal-oxygen bond in the gate dielectric layer 204:

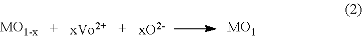

Performing the O₃ treatment operation may include flowing a mixture of ozone (O₃) and oxygen (O₂) over the gate dielectric layer 204. As noted herein, the flowing of the mixture may be performed at a same time as the UV light treatment, or after the UV light treatment is completed. A concentration of the ozone in the mixture may be included in a range of approximately 10% to approximately 25%. A concentration of ozone below 10% may result in an insufficient amount of ozone needed to replace weak metal-oxygen bonds or dangling bonds in the gate dielectric layer 204. A concentration of ozone greater than 25% may result in excess oxygen vacancies in the gate dielectric layer. However, other values and/or ranges for the concentration of ozone are within the scope of the present disclosure.

As shown in FIG. 4C, in the example implementation 406 illustrating the gate dielectric layer 204 prior to the UV light curing operation and the O₃ treatment operation, metal 408 (e.g., hafnium (Hf), aluminum (Al), zirconium (Zr), etc.) of the gate dielectric layer 204 may be bonded to oxygen 410 and/or to hydroxides 412. In addition, the gate dielectric layer 204 may include oxygen vacancies 414 and hydrogen ions 416. The combination of the UV light curing and O₃ treatment may remove or reduce unwanted impurities such as the hydrogen ions 416, the hydroxides 412 (e.g., hydroxide ions), and the oxygen vacancies 414 in the gate dielectric layer 204. The UV light curing operation may break hydrogen-oxygen bonds of hydroxides 412 bonded to metals 408 of high-k dielectric material.

In the example implementation 418 illustrating the gate dielectric layer 204 after the UV light curing operation and the O₃ treatment operation, the O₃ treatment process repairs broken bonds in the gate dielectric layer 204 by replacing the hydroxides 412 with oxygen 410 from the ozone, which strengthens metal-oxide bonds for the high-k dielectric material of the gate dielectric layer 204. Oxygen from the ozone of the O₃ treatment process also passivates the oxygen vacancies 414.

As shown in FIG. 4D, following the UV light curing and the O₃ treatment operations, the oxide-semiconductor channel layer 206 is formed over and/or on the gate dielectric layer 204. A deposition tool may be used to deposit the oxide-semiconductor channel layer 206 using an ALD technique, a CVD technique, a PVD technique, and/or another suitable deposition technique. In some implementations, a planarization tool is used to perform a CMP operation to planarize the oxide-semiconductor channel layer 206 after the oxide-semiconductor channel layer 206 is deposited.

The gate dielectric layer 204 may be in direct contact with (e.g., directly disposed on) the gate electrode 202. As noted herein, ozone from the O₃ treatment process provides oxygen to replace oxygen of weak and/or dangling metal-oxygen bonds in the gate dielectric layer 204, which strengthens metal-oxide bonds for the high-k dielectric material of the gate dielectric layer 204 to prevent or limit the formation of interfacial layers between the gate electrode 202 and the gate dielectric layer 204. The oxide-semiconductor channel layer 206 may be in direct contact with (e.g., directly disposed on) the gate dielectric layer 204. As noted herein, the strengthening of the metal-oxide bonds in the gate dielectric layer 204 may prevent or limit the formation of interfacial layers between the oxide-semiconductor channel layer 206 and the gate dielectric layer 204.

As shown in FIG. 4E, the capping layer 208 is formed over and/or on the oxide-semiconductor channel layer 206. A deposition tool may be used to deposit the capping layer 208 using an ALD technique, a CVD technique, a PVD technique, and/or another suitable deposition technique. In some implementations, the capping layer 208 is formed using an oxidation technique, in which a dielectric layer is deposited and an oxygen treatment or oxygen-based plasma is used to oxidize the dielectric layer to form the capping layer 208. In some implementations, a planarization tool is used to perform a CMP operation to planarize the capping layer 208 after the capping layer 208 is deposited.

As shown in FIG. 4F the oxide-semiconductor channel layer 206 and the capping layer 208 may be etched to define the channel of the transistor structure 120. In some implementations, a pattern in a photoresist layer is used to etch the oxide-semiconductor channel layer 206 and the capping layer 208. In these implementations, a deposition tool may be used to form the photoresist layer on the capping layer 208. An exposure tool may be used to expose the photoresist layer to a radiation source to pattern the photoresist layer. A developer tool may be used to develop and remove portions of the photoresist layer to expose the pattern. An etch tool may be used to etch the oxide-semiconductor channel layer 206 and the capping layer 208 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the oxide-semiconductor channel layer 206 and/or the capping layer 208 based on a pattern.

As shown in FIG. 4G, additional material of the ILD layer 112 may be formed over and/or on the capping layer 208. Moreover, the additional material of the ILD layer 112 may be formed such that the transistor structure 120 is encapsulated by the ILD layer 112. A deposition tool may be used to deposit the additional material of the ILD layer 112 using an ALD technique, a CVD technique, a PVD technique, an oxidation technique, and/or another suitable deposition technique. In some implementations, a planarization tool is used to perform a CMP operation to planarize the ILD layer 112 after the additional material of the ILD layer 112 is deposited.

As shown in FIG. 4H, recesses 420 and 422 may be formed in and/or through the ILD layer 112 such that portions of the top surface of the oxide-semiconductor channel layer 206 are exposed through the recesses 420 and 422. In some implementations, a pattern in a photoresist layer is used to etch the ILD layer 112 to form the recesses 420 and 422. In these implementations, a deposition tool may be used to form the photoresist layer on the ILD layer 112. An exposure tool may be used to expose the photoresist layer to a radiation source to pattern the photoresist layer. A developer tool may be used to develop and remove portions of the photoresist layer to expose the pattern. An etch tool may be used to etch the ILD layer 112 based on the pattern to form the recesses 420 and 422 in the ILD layer 112. The recesses 420 and 422 may also be formed through the capping layer 208. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 112 based on a pattern.

As shown in FIG. 4I, the source/drain electrodes 210 and 212 are respectively formed in the recesses 420 and 422. The source/drain electrodes 210 and 212 may land on the portions of the oxide-semiconductor channel layer 206 that are exposed in the recesses 420 and 422 such that the source/drain electrodes 210 and 212 are electrically coupled and/or physically coupled with the oxide-semiconductor channel layer 206.

A deposition tool may be used to deposit the source/drain electrodes 210 and 212 using a CVD technique, a PVD technique, an ALD technique, an electroplating technique, and/or another suitable deposition technique. In some implementations, a planarization tool may be used to planarize the top surfaces of the source/drain electrodes 210 and 212 after the source/drain electrodes 210 and 212 are deposited. The planarization of the source/drain electrodes 210 and 212 results in the top surfaces of the source/drain electrodes 210 and 212 and the top surface of the ILD layer 112 being substantially co-planar.

As indicated above, FIGS. 4A-4I are provided as an example. Other examples may differ from what is described with regard to FIGS. 4A-4I.

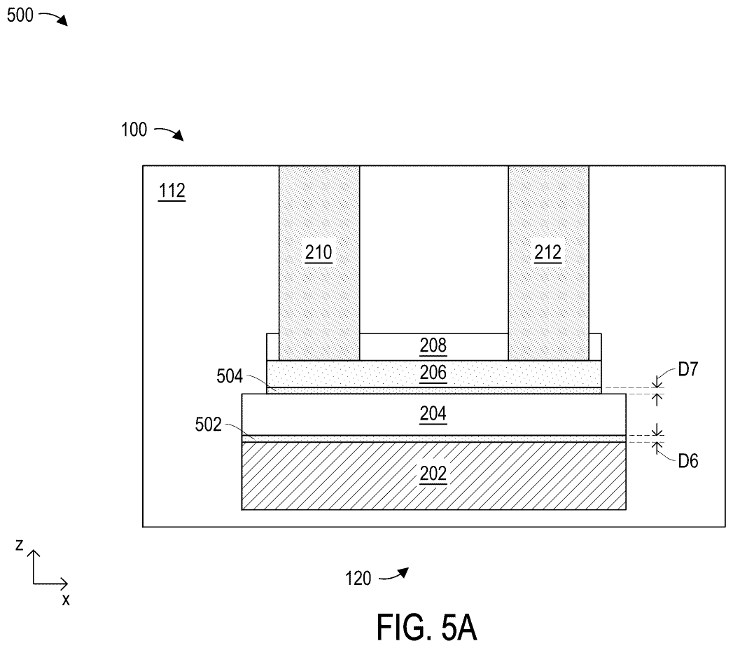

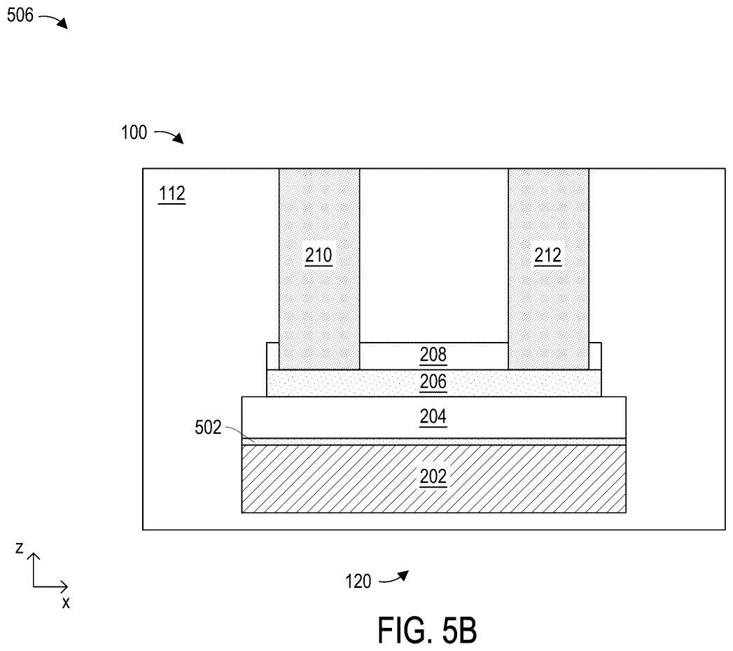

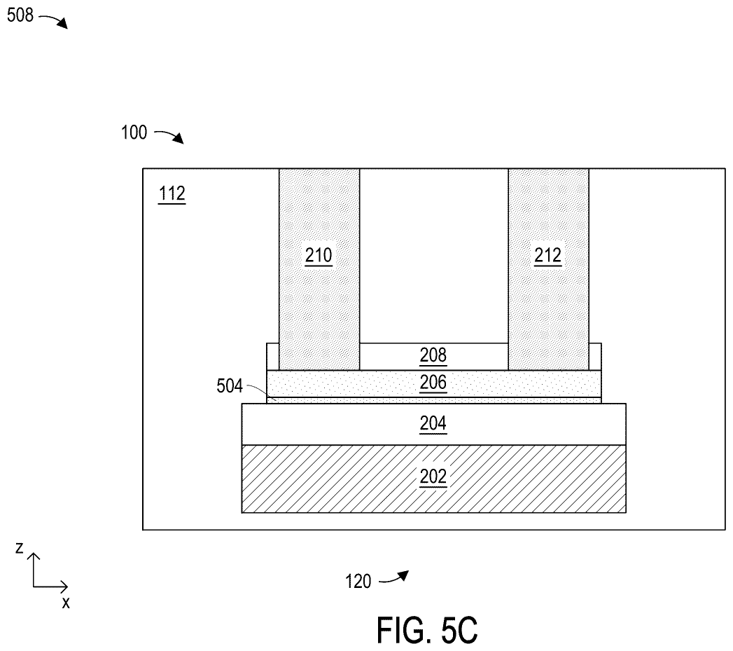

FIG. 5A is a diagram of an example implementation 500 of a transistor structure 120 described herein. As shown in FIG. 5A, the example implementation 500 of the transistor structure 120 is similar to the example implementation 200 of the transistor structure 120 illustrated and described in connection with FIGS. 2A and 2B. However, in the example implementation 500 of the transistor structure 120 in FIG. 5A, a first interfacial layer 502 is formed between the gate dielectric layer 204 and the gate electrode 202, and a second interfacial layer 504 is formed between the gate dielectric layer 204 and the oxide-semiconductor channel layer 206. As noted herein, the O₃ treatment process strengthens the metal-oxide bonds in the gate dielectric layer 204, which may prevent or limit the formation of interfacial layers between the gate dielectric layer 204 and the gate electrode 202 and/or between the gate dielectric layer 204 and the oxide-semiconductor channel layer 206. In this case, unlike the example implementation 200, the UV light curing and the O₃ treatment operations do not prevent the formation of interfacial layers, but instead limit the formation to small interfacial layers (e.g., first interfacial layer 502 and second interfacial layer 504) between the gate electrode layer 202 and the gate dielectric layer 204, and between the gate dielectric layer 204 and the oxide-semiconductor channel layer 206.

In some implementations, the first interfacial layer 502 may be a thin-film layer having a z-direction thickness (indicated in FIG. 5A as a dimension D6) that is included in a range of greater than 0 nanometers to approximately 0.5 nanometers. The UV light curing and the O₃ treatment operations may limit the z-direction thickness of the first interfacial layer 502 to approximately 0.5 nanometers or less. In some implementations, the first interfacial layer 502 may be formed as a discontinuous film having a thickness of approximately 0.5 nanometers or less. In some implementations, the first interfacial layer 502 is a metal-oxide including a metal of the gate electrode 202 (e.g., platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof) and oxygen from the gate dielectric layer 204.

In some implementations, the second interfacial layer 504 may be a thin-film layer having a z-direction thickness (indicated in FIG. 5A as a dimension D7) that is included in a range of greater than 0 nanometers to approximately 0.5 nanometers. The UV light curing and the O₃ treatment operations may limit the z-direction thickness of the second interfacial layer 504 to approximately 0.5 nanometers or less. In some implementations, the second interfacial layer 504 may be formed as a discontinuous film having a thickness of approximately 0.5 nanometers or less. In some implementations, the second interfacial layer 504 is a metal-oxide including a metal of the oxide-semiconductor channel layer 206 (e.g., tin (Sn), indium (In), gallium (Ga), zinc (Zn), tungsten (W), titanium (Ti), aluminum (Al), silver (Ag), vanadium (V), scandium (Sc), cerium (Ce), among other examples) and oxygen from the gate dielectric layer 204.

FIG. 5B is a diagram of an example implementation 506 of a transistor structure 120 described herein. As shown in FIG. 5B, the example implementation 506 of the transistor structure 120 is similar to the example implementation 500 of the transistor structure 120 illustrated and described in connection with FIG. 5A. In the example implementation 506 of the transistor structure 120 in FIG. 5B, the first interfacial layer 502 is formed between the gate dielectric layer 204 and the gate electrode 202, but there is no second interfacial layer 504 between the oxide-semiconductor channel layer 206 and the gate dielectric layer 204. Instead, in the example implementation 506, like the example implementation 200, the oxide-semiconductor channel layer 206 is in direct contact with (e.g., directly disposed on) the gate dielectric layer 204 without an intervening layer between the oxide-semiconductor channel layer 206 and the gate dielectric layer 204.

FIG. 5C is a diagram of an example implementation 508 of a transistor structure 120 described herein. As shown in FIG. 5C, the example implementation 508 of the transistor structure 120 is similar to the example implementation 500 of the transistor structure 120 illustrated and described in connection with FIG. 5A. In the example implementation 508 of the transistor structure 120 in FIG. 5C, the second interfacial layer 504 is formed between the gate dielectric layer 204 and the oxide-semiconductor channel layer 206, and there is no first interfacial layer 502 between the gate dielectric layer 204 and the gate electrode 202. Instead, in the example implementation 506, like the example implementation 200, the gate dielectric layer 204 is in direct contact with (e.g., directly disposed on) the gate electrode 202 without an intervening layer between the gate dielectric layer 204 and the gate electrode 202.

As indicated above, FIGS. 5A-5C are provided as an example. Other examples may differ from what is described with regard to FIGS. 5A-5C.

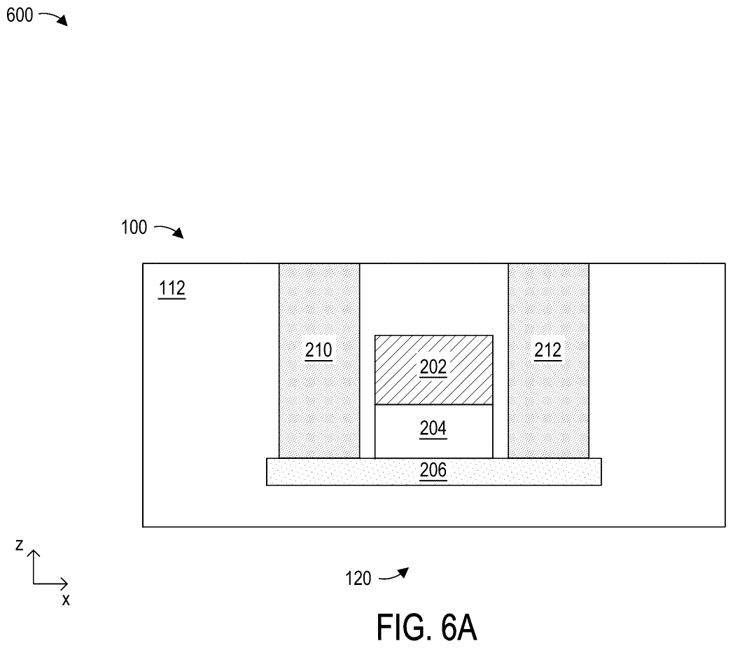

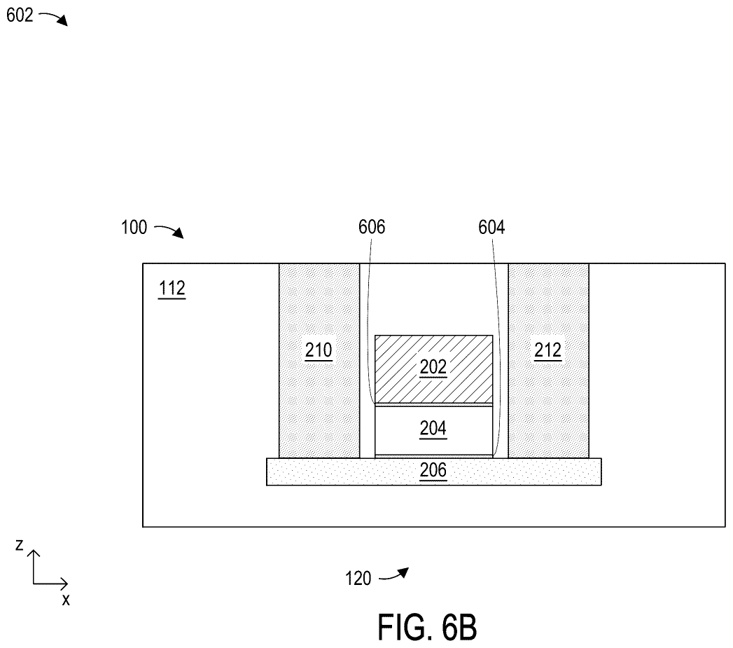

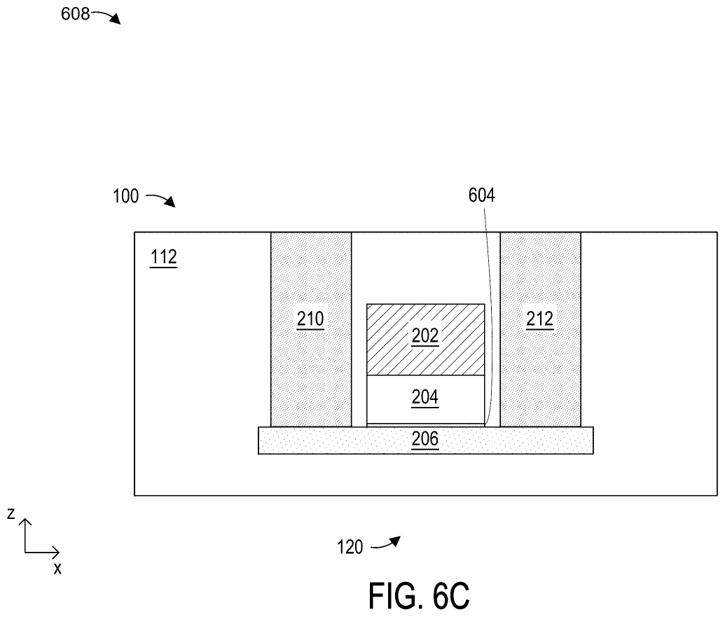

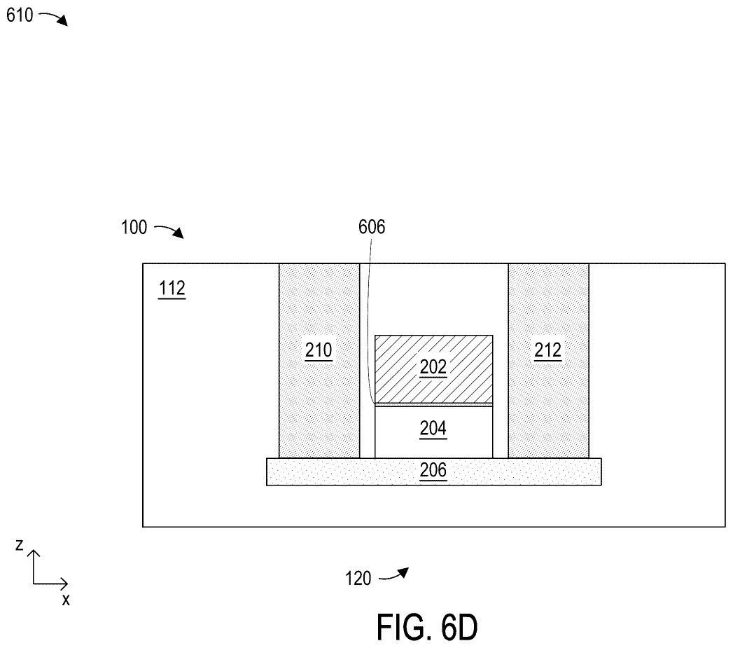

FIGS. 6A-6D are diagrams of example implementations of a transistor structure 120 described herein. FIG. 6A illustrates an example implementation 600 of the transistor structure 120. FIG. 6B illustrates an example implementation 602 of the transistor structure 120. FIG. 6C illustrates an example implementation 608 of the transistor structure 120. FIG. 6D illustrates an example implementation 610 of the transistor structure 120.

As shown in FIGS. 6A-6D, the example implementations 600, 602, 608, and 610 of the transistor structures 120 described herein are similar to the example implementation 200 of the transistor structure 120 illustrated and described in connection with FIG. 2A. For example, the example implementations 600, 602, 608, and 610 of the transistor structures 120 in FIGS. 6A-6D each include the gate electrode 202, the gate dielectric layer 204, the oxide-semiconductor channel layer 206, and the source/drain electrodes 210 and 212. However, the example implementations 600, 602, 608, and 610 of the transistor structures 120 in FIGS. 6A-6D each include a top gate electrode as opposed to the bottom gate electrode in the example implementation 200 in FIG. 2A. Thus, in the example implementations 600, 602, 608, and 610 of the transistor structures 120 in FIGS. 6A-6D, the gate dielectric layer 204 and the gate electrode 202 are included above the oxide-semiconductor channel layer 206, and the gate electrode 202 is included above the gate dielectric layer 204. The gate electrode 202 and the gate dielectric layer 204 are included between the source/drain electrodes 210 and 212. The gate dielectric layer 204 is included between the gate electrode 202 and the oxide-semiconductor channel layer 206.

The gate dielectric layer 204 may be formed prior to formation of the gate electrode 202. The gate dielectric layer 204 is also formed after formation of the oxide-semiconductor channel layer 206. Similar to what is described in connection with FIGS. 4B and 4C, a UV light curing operation and the O₃ treatment operation may be performed on the gate dielectric layer 204 to prevent or limit the formation of interfacial layers between the gate dielectric layer 204 and the gate electrode 202 and/or between the gate dielectric layer 204 and the oxide-semiconductor channel layer 206. In the example implementation 600, the gate dielectric layer 204 may be in direct contact with (e.g., directly disposed on) the oxide-semiconductor channel layer 206. As noted herein, ozone from the O₃ treatment process provides oxygen to replace oxygen of weak and/or dangling metal-oxygen bonds in the gate dielectric layer 204, which strengthens metal-oxide bonds for the high-k dielectric material of the gate dielectric layer 204 to prevent or limit the formation of interfacial layers between the gate dielectric layer 204 and the oxide-semiconductor channel layer 206.

In the example implementation 600, the gate electrode 202 may be in direct contact with (e.g., directly disposed on) the gate dielectric layer 204. As noted herein, the strengthening of the metal-oxide bonds in the gate dielectric layer 204 may prevent or limit the formation of interfacial layers between the gate electrode 202 and the gate dielectric layer 204.

As shown in the example implementation 602 of the transistor structure 120 in FIG. 6B, a first interfacial layer 604 is included on the oxide-semiconductor channel layer 206. The gate dielectric layer 204 is included on the first interfacial layer 604. A second interfacial layer 606 is included on the gate dielectric layer 204. The gate electrode 202 is included on the second interfacial layer 606. In some implementations, like the second interfacial layer 504, the first interfacial layer 604 may be a thin-film layer having a z-direction thickness that is included in a range of greater than 0 nanometers to approximately 0.5 nanometers. The UV light curing and the O₃ treatment operations performed on the gate dielectric layer 204 may limit the z-direction thickness of the first interfacial layer 604 to approximately 0.5 nanometers or less. In some implementations, the first interfacial layer 604 may be formed as a discontinuous film having a thickness of approximately 0.5 nanometers or less. Like the second interfacial layer 504, the first interfacial layer 604 may be a metal-oxide including a metal of the oxide-semiconductor channel layer 206 (e.g., tin (Sn), indium (In), gallium (Ga), zinc (Zn), tungsten (W), titanium (Ti), aluminum (Al), silver (Ag), vanadium (V), scandium (Sc), cerium (Ce), among other examples) and oxygen from the gate dielectric layer 204.

In some implementations, like the first interfacial layer 502, the second interfacial layer 606 may be a thin-film layer having a z-direction thickness that is included in a range of greater than 0 nanometers to approximately 0.5 nanometers. The UV light curing and the O₃ treatment operations performed on the gate dielectric layer 204 may limit the z-direction thickness of the second interfacial layer 606 to approximately 0.5 nanometers or less. In some implementations, the second interfacial layer 606 may be formed as a discontinuous film having a thickness of approximately 0.5 nanometers or less. Like the first interfacial layer 502, the second interfacial layer 606 is a metal-oxide including a metal of the gate electrode 202 (e.g., platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof) and oxygen from the gate dielectric layer 204.

As shown in FIG. 6C, the example implementation 608 of the transistor structure 120 is similar to the example implementation 602 of the transistor structure 120 illustrated and described in connection with FIG. 6B. However, in the example implementation 608 of the transistor structure 120, the second interfacial layer 606 is omitted and only the first interfacial layer 604 is included. Thus, in the example implementation 608 of the transistor structure 120, the gate electrode 202 is included on (and formed on) the gate dielectric layer 204 without the intervening second interfacial layer 606 between the gate electrode 202 and the gate dielectric layer 204.

As shown in FIG. 6D, the example implementation 610 of the transistor structure 120 is similar to the example implementation 602 of the transistor structure 120 illustrated and described in connection with FIG. 6B. However, in the example implementation 610 of the transistor structure 120, the first interfacial layer 604 is omitted and only the second interfacial layer 606 is included. Thus, in the example implementation 610 of the transistor structure 120, the gate dielectric layer 204 is included on (and formed on) the oxide-semiconductor channel layer 206 without the intervening first interfacial layer 604 between the gate dielectric layer 204 and the oxide-semiconductor channel layer 206.

As indicated above, FIGS. 6A-6D provided as examples. Other examples may differ from what is described with regard to FIGS. 6A-6D.

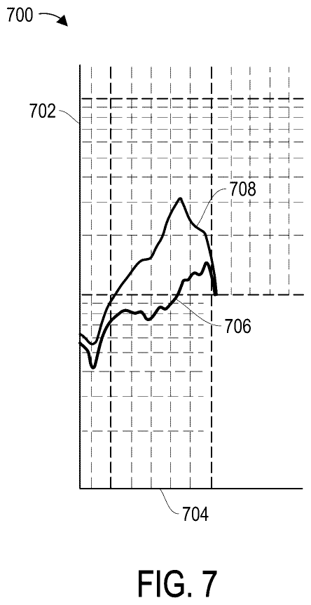

FIG. 7 is a graph 700 illustrating a hydrogen profile in a gate dielectric layer of a transistor structure described herein. In the graph 700, the vertical axis 702 represents a concentration of hydrogen in a gate dielectric layer, and the horizontal axis 704 represents a depth of the gate dielectric layer. The value of the concentration increases in the upward direction, and the depth increases in the right-hand direction. The plot 706 represents a hydrogen profile in a gate dielectric layer 204 of a transistor structure 120 after performance of the UV light curing operation and the O₃ treatment operation on the gate dielectric layer 204, and the plot 708 represents a hydrogen profile in a gate dielectric layer 204 of a transistor structure 120 prior to and/or without performance of the UV light curing operation and the O₃ treatment operation on the gate dielectric layer 204. As can be seen, over a particular depth range, the concentration of hydrogen in a gate dielectric layer 204 that has been subject to the UV light curing operation and the O₃ treatment operation is less than the concentration of hydrogen as a function of depth in the gate dielectric layer 204 that has not been subject to the UV light curing operation and the O₃ treatment operation. The combination of the UV light curing and O₃ treatment may remove or reduce unwanted impurities such as hydrogen ions (H⁺) and hydroxide ions (OH⁻) that may be formed in the gate dielectric layer 204 between an oxide-semiconductor channel 206 and a gate electrode 202 of the transistor structure 120, thereby reducing the hydrogen concentration of the gate dielectric layer 204. The UV light curing operation may break hydrogen bonds in the gate dielectric layer 204. The hydrogen bonds may include, for example, hydrogen-oxygen bonds of hydroxides bonded to metals of high-k dielectric material.

For example, over a depth range of approximately 0 angstroms to approximately 100 angstroms, the concentration of hydrogen in a gate dielectric layer 204 that has been subject to the UV light curing operation and the O₃ treatment operation may be included in a range of approximately 6×10²⁰ cm⁻³ to approximately 3×10²¹ cm⁻³. Over the depth range of approximately 0 angstroms to approximately 100 angstroms, the concentration of hydrogen in the gate dielectric layer 204 that has not been subject to the UV light curing operation and the O₃ treatment operation may be included in a range of approximately 7×10²⁰ cm⁻³ to approximately 5×10²¹ cm⁻³. However, other values and/or ranges for the hydrogen concentration of the gate dielectric layer 204 are within the scope of the present disclosure.

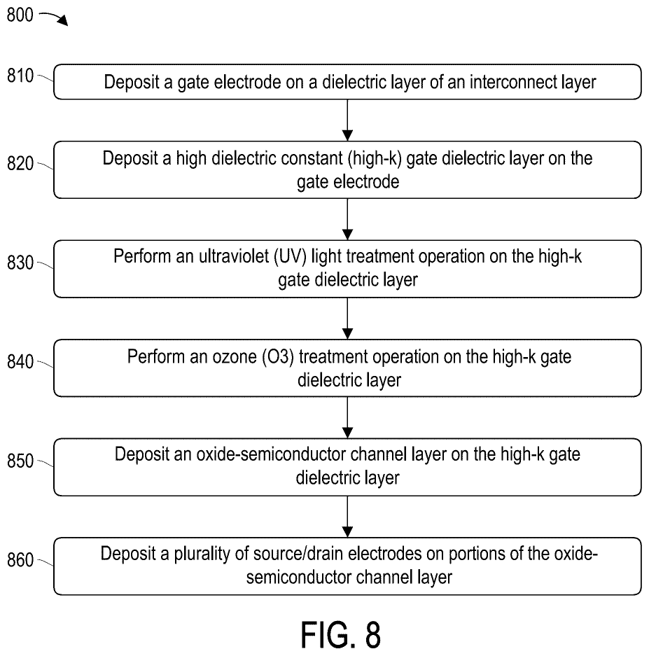

FIG. 8 is a flowchart of an example process 800 associated with a method of forming a semiconductor device. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include depositing a gate electrode on a dielectric layer of an interconnect layer (block 810). For example, one or more semiconductor processing tools may be used to deposit a gate electrode (e.g., gate electrode 202) on a dielectric layer (e.g., ILD layer 112) of an interconnect layer (e.g., interconnect layer 104), as described herein.

As further shown in FIG. 8, process 800 may include depositing a high dielectric constant (high-k) gate dielectric layer on the gate electrode (block 820). For example, one or more semiconductor processing tools may be used to deposit a high dielectric constant (high-k) gate dielectric layer (e.g., gate dielectric layer 204) on the gate electrode, as described herein.

As further shown in FIG. 8, process 800 may include performing an ultraviolet (UV) light treatment operation on the high-k gate dielectric layer (block 830). For example, one or more semiconductor processing tools may be used to perform an ultraviolet (UV) light treatment operation on the high-k gate dielectric layer, as described herein.

As further shown in FIG. 8, process 800 may include performing an ozone (O₃) treatment operation on the high-k gate dielectric layer (block 840). For example, one or more semiconductor processing tools may be used to perform an ozone (O₃) treatment operation on the high-k gate dielectric layer, as described herein.

As further shown in FIG. 8, process 800 may include depositing an oxide-semiconductor channel layer on the high-k gate dielectric layer (block 850). For example, one or more semiconductor processing tools may be used to deposit an oxide-semiconductor channel layer (e.g., oxide-semiconductor channel layer 206) on the high-k gate dielectric layer, as described herein.

As further shown in FIG. 8, process 800 may include depositing a plurality of source/drain electrodes on portions of the oxide-semiconductor channel layer (block 860). For example, one or more semiconductor processing tools may be used to deposit a plurality of source/drain electrodes (e.g., source/drain electrodes 210 and 212) on portions of the oxide-semiconductor channel layer, as described herein.

Process 800 may include additional implementations, such as any single implementation or any combination of implementations described below and/or in connection with one or more other processes described elsewhere herein.

In a first implementation, the UV light treatment operation and the O₃ treatment operation are performed simultaneously.

In a second implementation, alone or in combination with the first implementation, the O₃ treatment operation is performed after the UV light treatment operation.

In a third implementation, alone or in combination with one or more of the first and second implementations, performing the UV light treatment operation includes exposing the high-k gate dielectric layer to UV light having a wavelength included in a range of approximately 100 nanometers to approximately 440 nanometers.

In a fourth implementation, alone or in combination with one or more of the first through third implementations, a time for performing the UV light treatment operation is included in a range of approximately 30 seconds to approximately 300 seconds.

In a fifth implementation, alone or in combination with one or more of the first through fourth implementations, performing the O₃ treatment operation includes flowing a mixture of O₃ and oxygen (O₂) over the high-k gate dielectric layer, and where a concentration of the O₃ in the mixture is included in a range of approximately 10% to approximately 25%.

In a sixth implementation, alone or in combination with one or more of the first through fifth implementations, performing the O₃ treatment operation includes flowing a mixture of O₃ and oxygen (O₂) over the high-k gate dielectric layer, where at least a portion of the O₃ in the mixture is formed into one or more oxygen ions, and where the one or more oxygen ions passivate one or more oxygen vacancies in the high-k gate dielectric layer.

In a seventh implementation, alone or in combination with one or more of the first through sixth implementations, energy generated by UV light from the UV light treatment operation causes breaking of one or more hydrogen-oxygen bonds in the high-k gate dielectric layer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

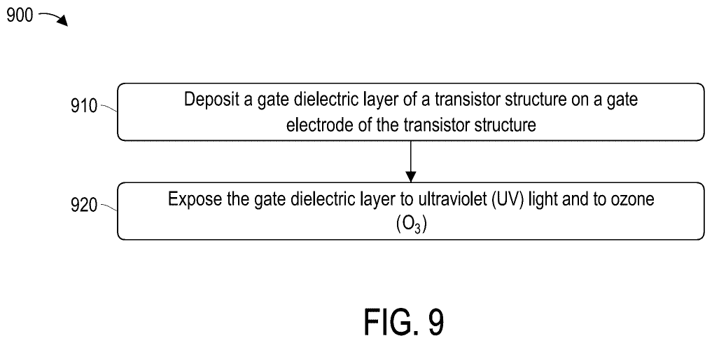

FIG. 9 is a flowchart of an example process 900 associated with a method of forming a semiconductor device. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include depositing a gate dielectric layer of a transistor structure on a gate electrode of the transistor structure (block 910). For example, one or more semiconductor processing tools may be used to deposit a gate dielectric layer (e.g., gate dielectric layer 204) of a transistor structure (e.g., transistor structure 120) on a gate electrode (e.g., gate electrode 202) of the transistor structure, as described herein. In some implementations, the transistor structure is formed in an interconnect layer (e.g., interconnect layer 104) of a semiconductor device (e.g., semiconductor device 100).

As further shown in FIG. 9, process 900 may include exposing the gate dielectric layer to ultraviolet (UV) light and to ozone (O₃) (block 920). For example, one or more semiconductor processing tools may be used to expose the gate dielectric layer to ultraviolet (UV) light and to ozone (O₃), as described herein.

Process 900 may include additional implementations, such as any single implementation or any combination of implementations described below and/or in connection with one or more other processes described elsewhere herein.

In a first implementation, the gate electrode and the gate dielectric layer are in direct contact.

In a second implementation, alone or in combination with the first implementation, process 900 includes depositing an oxide-semiconductor channel layer (e.g., oxide-semiconductor channel layer 206) on the gate dielectric layer, where the oxide-semiconductor channel layer and the gate dielectric layer are in direct contact.

In a third implementation, alone or in combination with one or more of the first and second implementations, process 900 includes depositing a capping layer (e.g., capping layer 208) on the oxide-semiconductor channel layer, depositing a first source/drain electrode (e.g. source/drain electrode 210) through a first portion of the capping layer onto a first portion of the oxide-semiconductor channel layer, and depositing a second source/drain electrode (e.g., source/drain electrode 212) through a second portion of the capping layer onto a second portion of the oxide-semiconductor channel layer.

In a fourth implementation, alone or in combination with one or more of the first through third implementations, an interfacial layer (e.g., first interfacial layer 502, second interfacial layer 606) including a material of the gate electrode and oxygen from the gate dielectric layer is formed between the gate electrode and the gate dielectric layer, and a thickness (e.g., dimension D6) of the interfacial layer is included in a range of greater than 0 nanometers to approximately 0.5 nanometers.

In a fifth implementation, alone or in combination with one or more of the first through fourth implementations, process 900 includes depositing an oxide-semiconductor channel layer (e.g., oxide-semiconductor channel layer 206) on the gate dielectric layer, where an interfacial layer (e.g., second interfacial layer 504, first interfacial layer 604) including a material of the oxide-semiconductor channel layer and oxygen from the gate dielectric layer is formed between the oxide-semiconductor channel layer and the gate dielectric layer, and where a thickness (e.g., dimension D7) of the interfacial layer is included in a range of greater than 0 nanometers to approximately 0.5 nanometers.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a transistor structure may be formed in an interconnect layer of a semiconductor device. The transistor structure is formed in a process that includes performing ultraviolet (UV) light curing and ozone (O₃) treatment operations on a gate dielectric layer of the transistor structure. The combination of the UV light curing and O₃ treatment may remove or reduce unwanted impurities such as hydrogen ions (H⁺), hydroxide ions (OH⁻), and oxygen vacancies (Vo) that may be formed in the gate dielectric layer between an oxide-semiconductor channel and a gate electrode of the transistor structure. The UV light curing operation may break hydrogen bonds in the gate dielectric layer. The hydrogen bonds may include, for example, hydrogen-oxygen bonds of hydroxides bonded to metals of high-k dielectric material. The O₃ treatment process repairs the broken bonds by replacing oxygen of weak and/or dangling metal-oxygen bonds with oxygen from the ozone, which strengthens metal-oxide bonds for the high-k dielectric material of the gate dielectric layer. The strengthening of the metal-oxide bonds in the gate dielectric layer may prevent oxygen from the gate dielectric layer from reacting with metals in the adjacent gate electrode and oxide-semiconductor channel. Oxygen from the ozone of the O₃ treatment process also passivates oxygen vacancies in the gate dielectric layer. The passivated oxygen vacancies in the gate dielectric layer may reduce charge carrier concentration in the gate dielectric layer. As a result, the transistor structure may have a higher breakdown voltage, increased reliability, and increased performance in comparison to a transistor structure manufactured without using the UV light curing and O₃ treatment processes.

As described in greater detail above, some implementations described herein provide a method. The method includes depositing a gate electrode on a dielectric layer of an interconnect layer. The method includes depositing a high dielectric constant (high-k) gate dielectric layer on the gate electrode. The method includes performing an ultraviolet (UV) light treatment operation on the high-k gate dielectric layer. The method includes performing an ozone (O₃) treatment operation on the high-k gate dielectric layer. The method includes depositing an oxide-semiconductor channel layer on the high-k gate dielectric layer. The method includes depositing a plurality of source/drain electrodes on portions of the oxide-semiconductor channel layer.

As described in greater detail above, some implementations described herein provide a method. The method includes depositing a gate dielectric layer of a transistor structure on a gate electrode of the transistor structure, where the transistor structure is formed in an interconnect layer of a semiconductor device. The method includes exposing the gate dielectric layer to ultraviolet (UV) light and to ozone (O₃).

As described in greater detail above, some implementations described herein provide a semiconductor structure. The semiconductor structure includes a gate electrode. The semiconductor structure includes an oxide-semiconductor channel layer. The semiconductor structure includes a high dielectric constant (high-k) gate dielectric layer between the gate electrode and the oxide-semiconductor channel layer, where the high-k gate dielectric layer is in direct contact with at least one of the gate electrode or the oxide-semiconductor channel layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a gate electrode on a dielectric layer of an interconnect layer;
depositing a high dielectric constant (high-k) gate dielectric layer on the gate electrode;
performing an ultraviolet (UV) light treatment operation on the high-k gate dielectric layer;
performing an ozone (O₃) treatment operation on the high-k gate dielectric layer;
depositing an oxide-semiconductor channel layer on the high-k gate dielectric layer; and
depositing a plurality of source/drain electrodes on portions of the oxide-semiconductor channel layer.

2. The method of claim 1, wherein the UV light treatment operation and the O₃ treatment operation are performed simultaneously.

3. The method of claim 1, wherein the O₃ treatment operation is performed after the UV light treatment operation.

4. The method of claim 1, wherein performing the UV light treatment operation comprises exposing the high-k gate dielectric layer to UV light having a wavelength included in a range of approximately 100 nanometers to approximately 440 nanometers.

5. The method of claim 1, wherein a time for performing the UV light treatment operation is included in a range of approximately 30 seconds to approximately 300 seconds.

6. The method of claim 1, wherein performing the O₃ treatment operation comprises flowing a mixture of O₃ and oxygen (O₂) over the high-k gate dielectric layer, and
wherein a concentration of the O₃ in the mixture is included in a range of approximately 10% to approximately 25%.

7. The method of claim 1, wherein performing the O₃ treatment operation comprises flowing a mixture of O₃ and oxygen (O₂) over the high-k gate dielectric layer,
wherein at least a portion of the O₃ in the mixture is formed into one or more oxygen ions, and
wherein the one or more oxygen ions passivate one or more oxygen vacancies in the high-k gate dielectric layer.

8. The method of claim 1, wherein energy generated by UV light from the UV light treatment operation causes breaking of one or more hydrogen-oxygen bonds in the high-k gate dielectric layer.

9. A method, comprising:
depositing a gate dielectric layer of a transistor structure on a gate electrode of the transistor structure,
wherein the transistor structure is formed in an interconnect layer of a semiconductor device; and
exposing the gate dielectric layer to ultraviolet (UV) light and to ozone (O₃).

10. The method of claim 9, wherein the gate electrode and the gate dielectric layer are in direct contact.

11. The method of claim 9, further comprising depositing an oxide-semiconductor channel layer on the gate dielectric layer,
wherein the oxide-semiconductor channel layer and the gate dielectric layer are in direct contact.

12. The method of claim 11, further comprising:
depositing a capping layer on the oxide-semiconductor channel layer;
depositing a first source/drain electrode through a first portion of the capping layer onto a first portion of the oxide-semiconductor channel layer; and
depositing a second source/drain electrode through a second portion of the capping layer onto a second portion of the oxide-semiconductor channel layer.

13. The method of claim 9, wherein an interfacial layer comprising a material of the gate electrode and oxygen from the gate dielectric layer is formed between the gate electrode and the gate dielectric layer, and
wherein a thickness of the interfacial layer is included in a range of greater than 0 nanometers to approximately 0.5 nanometers.

14. The method of claim 9, further comprising depositing an oxide-semiconductor channel layer on the gate dielectric layer,
wherein an interfacial layer comprising a material of the oxide-semiconductor channel layer and oxygen from the gate dielectric layer is formed between the oxide-semiconductor channel layer and the gate dielectric layer, and
wherein a thickness of the interfacial layer is included in a range of greater than 0 nanometers to approximately 0.5 nanometers.

15. A semiconductor structure, comprising:
a gate electrode;
an oxide-semiconductor channel layer; and
a high dielectric constant (high-k) gate dielectric layer between the gate electrode and the oxide-semiconductor channel layer,
wherein the high-k gate dielectric layer is in direct contact with at least one of the gate electrode or the oxide-semiconductor channel layer.

16. The semiconductor structure of claim 15, wherein the high-k gate dielectric layer comprises hydrogen, and
wherein a concentration of the hydrogen in the high-k gate dielectric layer is included in a range from approximately 6×10²⁰ cm⁻³ to approximately 3×10²¹ cm⁻³.

17. The semiconductor structure of claim 15, wherein a first surface of the high-k gate dielectric layer is in direct contact with the gate electrode, and
wherein a second surface of the high-k gate dielectric layer opposite the first surface is in direct contact with the oxide-semiconductor channel layer.

18. The semiconductor structure of claim 15, further comprising an interfacial layer between the high-k gate dielectric layer and the gate electrode,
wherein the high-k gate dielectric layer is in direct contact with the oxide-semiconductor channel layer.

19. The semiconductor structure of claim 18, wherein a thickness of the interfacial layer is included in a range of greater than 0 nanometers to approximately 0.5 nanometers.

20. The semiconductor structure of claim 15, further comprising an interfacial layer between the high-k gate dielectric layer and the oxide-semiconductor channel layer,
wherein the high-k gate dielectric layer is in direct contact with the gate electrode.
